(19) United States
(12) Patent Application Publication
(10) Pub. No.: US 2014/0051222 A1
(43) Pub. Date: Feb. 20, 2014

(54) METHOD OF MANUFACTURING SEMICONDUCTOR DEVICE

(71) Applicant: FUJITSU SEMICONDUCTOR LIMITED, Yokohama-shi (JP)

(72) Inventors: MASANORI TERAHARA, Kuwana (JP); Akira Katakami, Kuwana (JP); Eiji Yoshida, Yokohama (JP); AKIHIKO HARADA, Kuwana (JP)

(73) Assignee: FUJITSU SEMICONDUCTOR LIMITED, Yokohama-shi (JP)

(21) Appl. No.: 13/963,263

(22) Filed: Aug. 9, 2013

(30) Foreign Application Priority Data
Aug. 17, 2012 (JP) 2012-180887

(51) Int. Cl. H01L 21/762

(52) U.S. Cl. CPC H01L 21/76224
USPC 438/296

(57) ABSTRACT

A method of manufacturing a semiconductor device includes forming a first insulating film above a semiconductor substrate, patterning the first insulating film to form a first and a second opening, forming a first sidewall film on side walls of the first and the second openings, etching the semiconductor substrate with the first insulating film and the first sidewall film as a mask to dig down the first opening and the second opening, removing the first sidewall film to form a first offset portion in the first opening and a second offset portion in the second opening, the first and the second offset portion including a part of a surface of the semiconductor substrate, and etching a bottom of the first opening with the first insulating film as a mask.

### CROSS-REFERENCE TO RELATED APPLICATION

This application is based upon and claims the benefit of priority of the prior Japanese Patent Application No. 2012-180887, filed on Aug. 17, 2012, the entire contents of which are incorporated herein by reference.

### FIELD

The embodiments discussed herein are related to a method of manufacturing a semiconductor device.

### BACKGROUND

As a transistor structure for decreasing the power consumption of semiconductor devices, the structure called DTMOS (Dynamic Threshold Voltage MOSFET) is proposed. The DTMOS is a transistor structure that the body electrodes of the respective transistors are isolated by the use of SOI substrate and the gate electrode and the body electrode are electrically connected. The DTMOS can make the drive current large when the transistor is on, and, when the transistor is off, can make the threshold voltage higher relatively to the threshold voltage at the ON state, whereby the leakage current can be suppressed, and low electric power consumption can be realized.

As a transistor structure for decreasing the body resistance of the DTMOS, a structure called B-DTMOS (Bulk Dynamic Threshold Voltage MOSFET) is proposed. The B-DTMOS is a transistor structure that the body electrodes of the respective transistors are isolated by the use of double well and trench device isolation formed in a bulk substrate. The B-DTMOS can easily control the thickness of the body region, and the body resistance can be drastically decreased.

The followings are examples of related: Japanese Laid-open Patent Publication No. 07-273184; Japanese Laid-open Patent Publication No. 08-172124; Japanese Laid-open Patent Publication No. 11-045890; Japanese Laid-open Patent Publication No. 2000-012675; Japanese Laid-open Patent Publication No. 2000-150634; Japanese Laid-open Patent Publication No. 2000-223704; and Japanese Laid-open Patent Publication No. 2005-191331.

For higher performances and lower power consumption of the transistors, a method of manufacturing a semiconductor device which can realize transistors whose leakage current is smaller is expected.

### SUMMARY

According to one aspect of the embodiments, there is provided a method of manufacturing a semiconductor device including forming a first insulating film above a semiconductor substrate, patterning the first insulating film to form a first opening and a second opening in the first insulating film, forming a first sidewall film on a side wall of the first opening and a side wall of the second opening, etching the semiconductor substrate with the first insulating film and the first sidewall film as a mask to dig down the first opening and the second opening into the semiconductor substrate, after digging down the first opening and the second opening into the semiconductor substrate, removing the first sidewall film to form a first offset portion in the first opening and a second offset portion in the second opening, the first offset portion and the second offset portion including a part of a surface of the semiconductor substrate, and etching a bottom of the first opening with the first insulating film as a mask.

According to another aspect of the embodiments, there is provided a method of manufacturing a semiconductor device including forming a first insulating film above a semiconductor substrate, patterning the first insulating film to form a first opening and a second opening in the first insulating film, etching the semiconductor substrate with the first insulating film as a mask to dig down the first opening and the second opening into the semiconductor substrate, etching a bottom of the first opening with the first insulating film as a mask, forming in the first opening a first buried insulating film having an upper surface positioned higher than a surface of the semiconductor substrate, and forming in the second opening a second buried insulating film having an upper surface positioned higher than the surface of the semiconductor substrate, after forming the first buried insulating film and the second buried insulating film, removing the first insulating film, after removing the first insulating film, forming a first sidewall film on a side wall of the first buried insulating film and the second buried insulating film positioned higher than the surface of the semiconductor substrate to form a first device isolation insulating film including the first buried insulating film and the first sidewall film, and a second device isolation insulating film including the second buried insulating film and the first sidewall film.

The object and advantages of the embodiment will be realized and attained by means of the elements and combinations particularly pointed out in the claims.

It is to be understood that both the foregoing general description and the following detailed description are exemplary and explanatory and are not restrictive of the embodiments, as claimed.

### BRIEF DESCRIPTION OF DRAWINGS

FIG. 1 is a plan view illustrating a structure of a semiconductor device according to a first embodiment;

FIGS. 2A and 2B are diagrammatic cross-sectional views illustrating the structure of the semiconductor device according to the first embodiment;

FIGS. 3A-3Q are cross-sectional views illustrating a method of manufacturing a semiconductor device according to the first embodiment (Part 1);

FIGS. 4A-4C are cross-sectional views illustrating the method of manufacturing the semiconductor device according to the first embodiment (Part 2);

FIGS. 5A and 5B are cross-sectional views explaining the problems caused when the recess is formed on the peripheral surface of the device isolation insulating film;

FIGS. 6A and 6B are diagrammatic cross-sectional views illustrating a structure of a semiconductor device according to a second embodiment;

FIGS. 7A-7G are cross-sectional views illustrating a method of manufacturing a semiconductor device according to the second embodiment (Part 1);

FIGS. 8A-8D are cross-sectional views illustrating the method of manufacturing the semiconductor device according to the second embodiment (Part 2);

FIGS. 9 and 10 are graphs illustrating the subthreshold characteristics of the n-channel transistor manufactured by using a device isolation insulating film without extension;

FIG. 11 is a graph illustrating the subthreshold characteristics of the n-channel transistor manufactured by using a device isolation insulating film with extension;

FIGS. 12A-12I are cross-sectional views illustrating a method of manufacturing a semiconductor device according to a third embodiment; and

FIGS. 13A-13K are cross-sectional views illustrating a method of manufacturing a semiconductor device according to a fourth embodiment.

### DESCRIPTION OF EMBODIMENTS

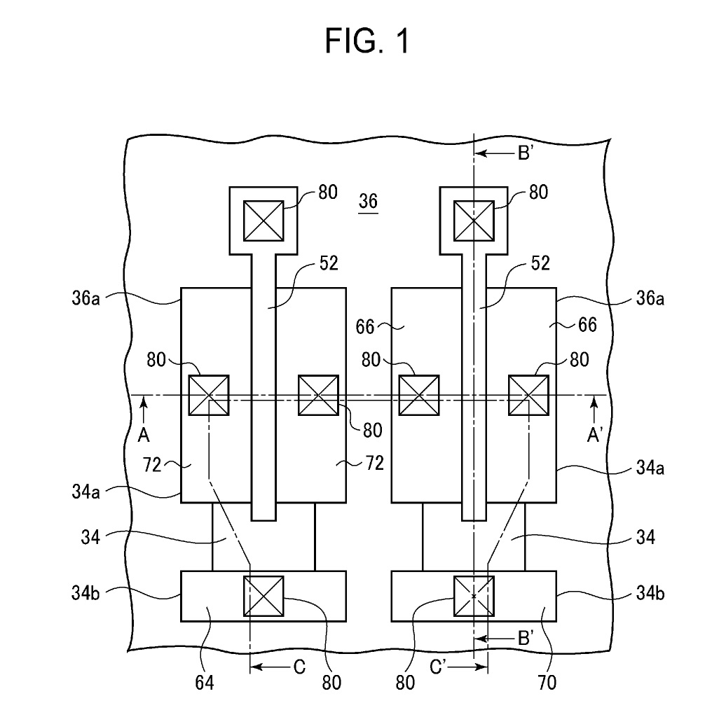

A semiconductor device and a method of manufacturing the semiconductor device according to a first embodiment will be described with reference to FIGS. 1 to 5B.

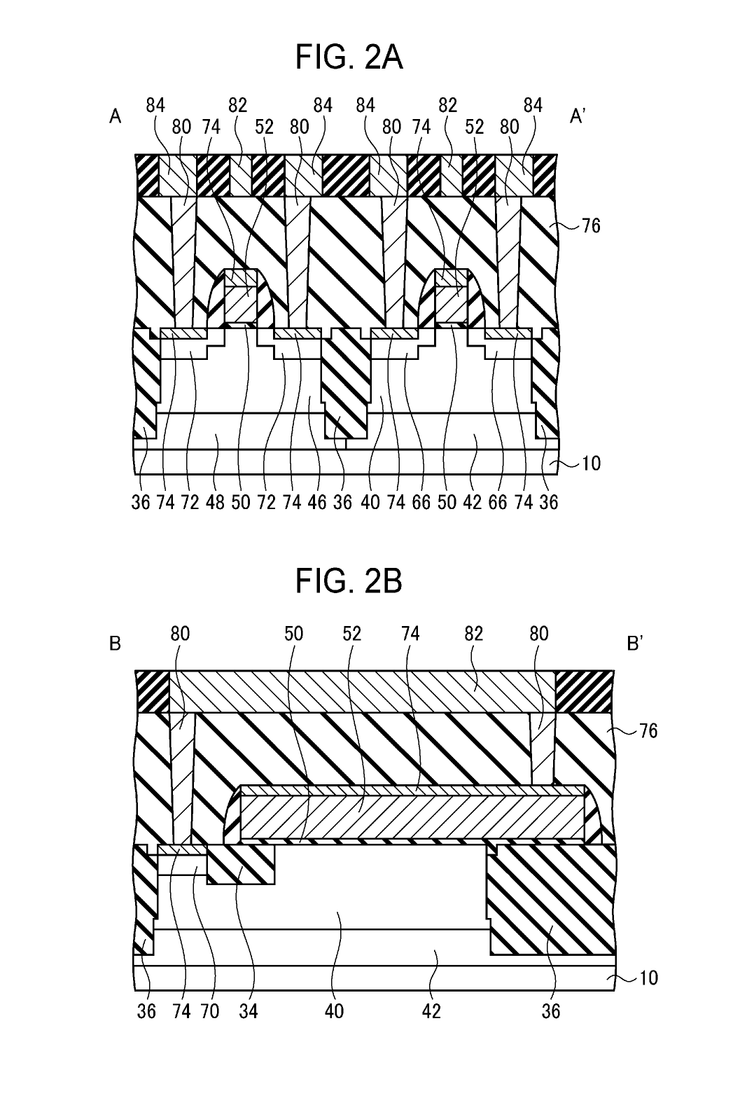

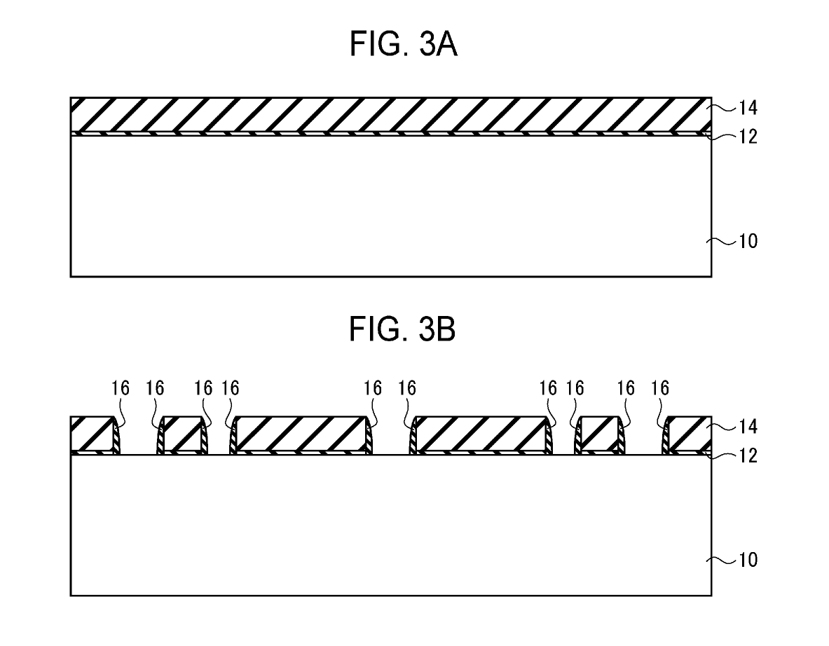

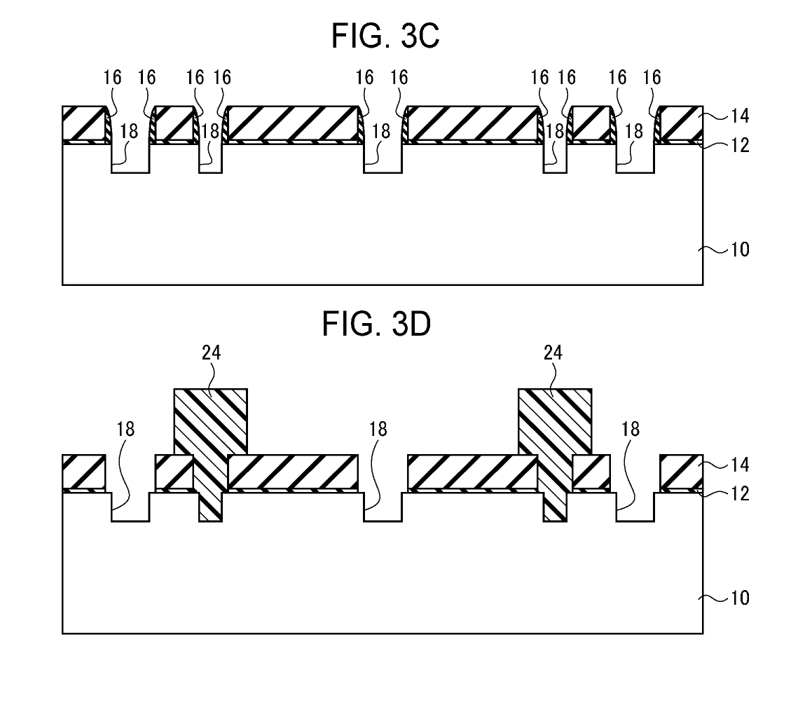

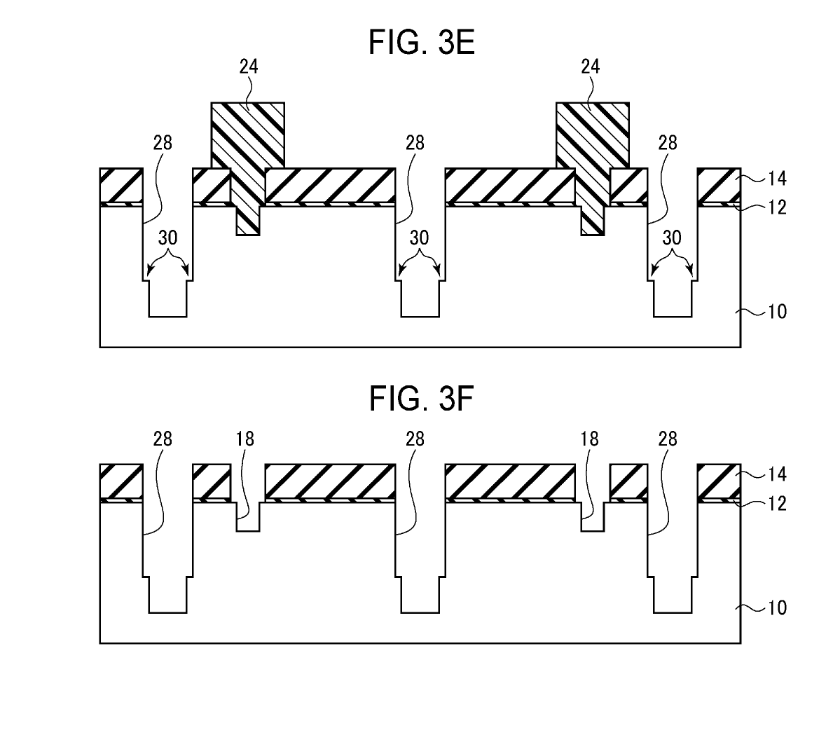

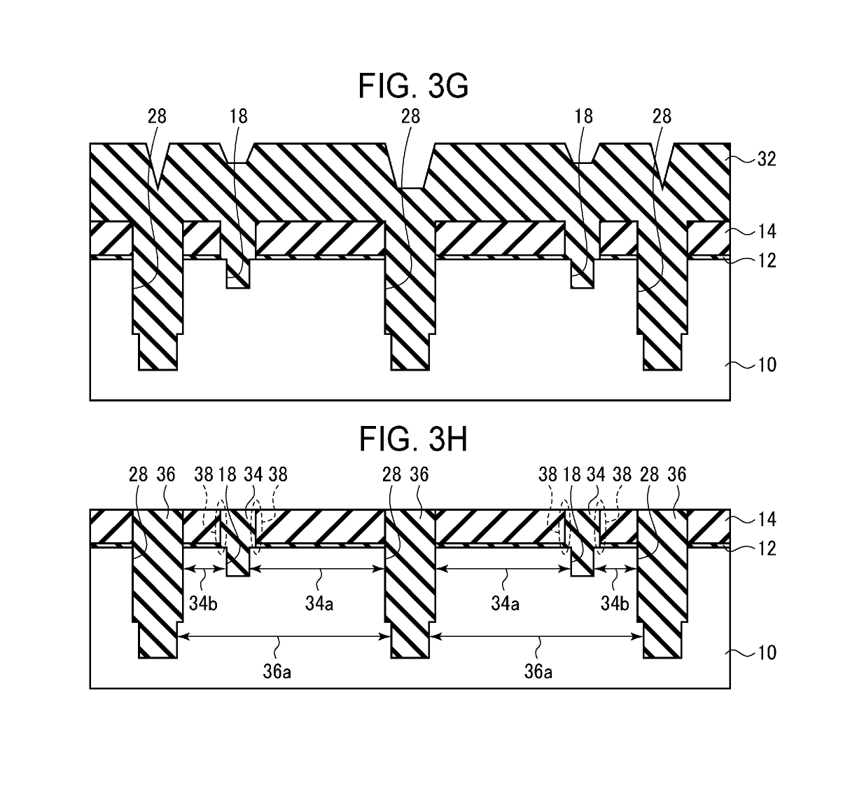

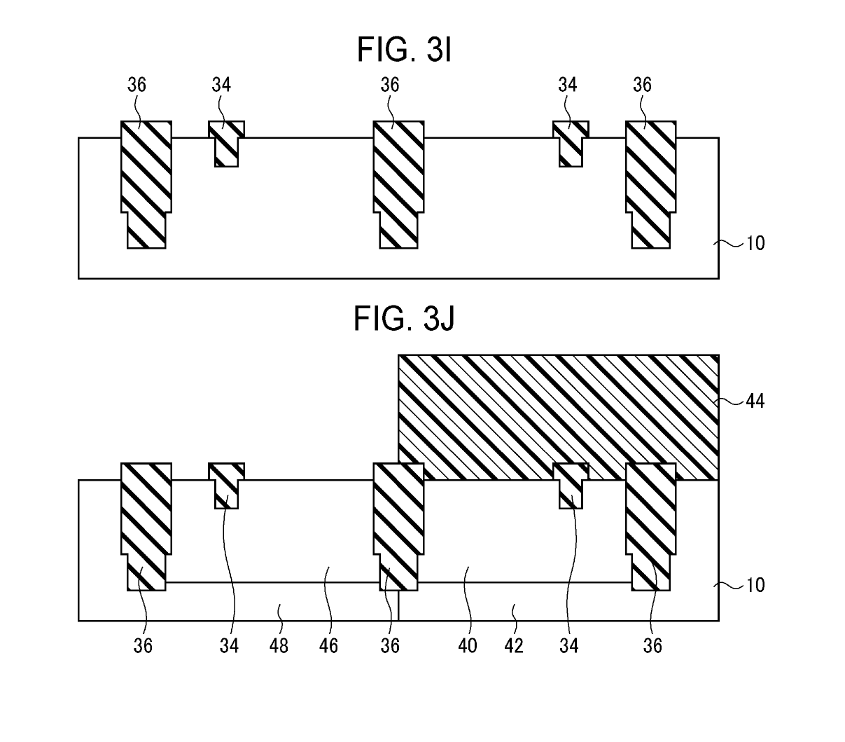

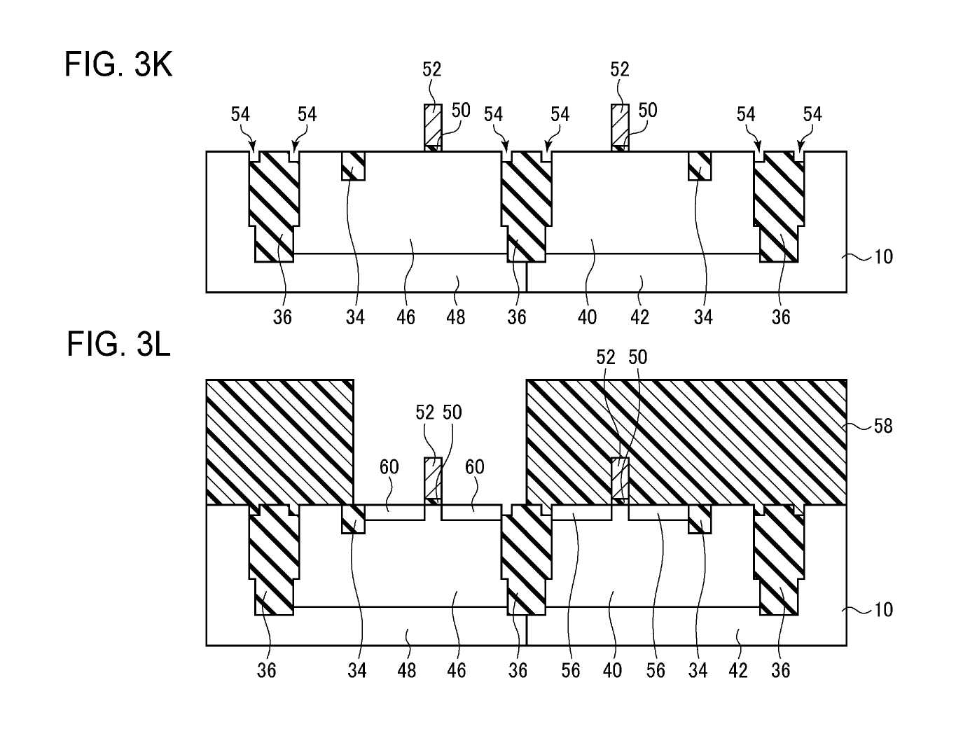

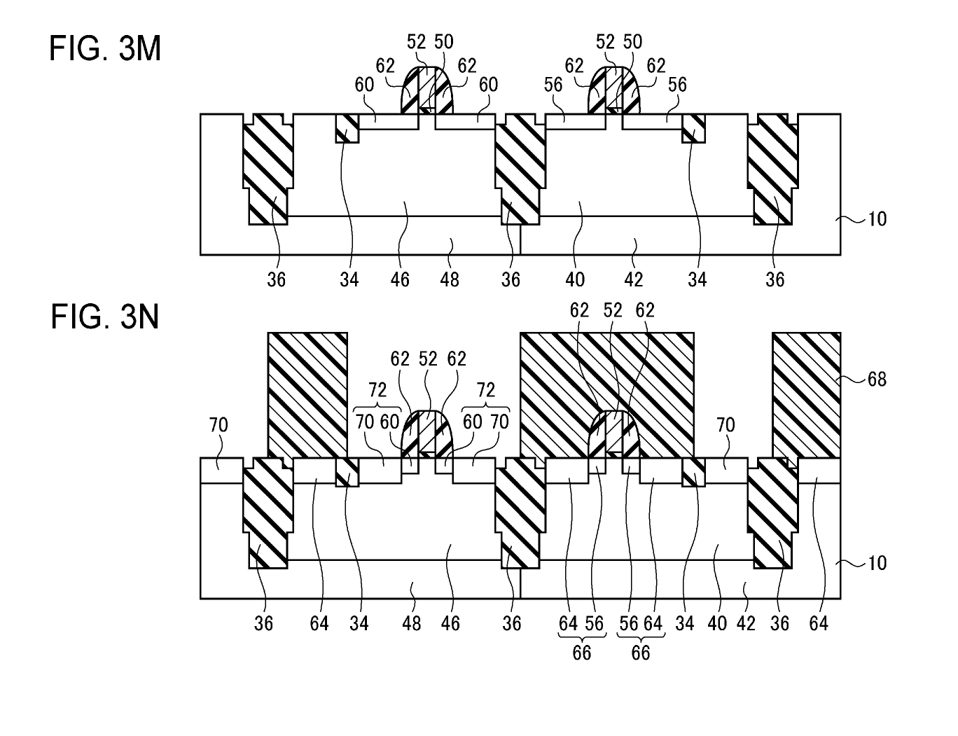

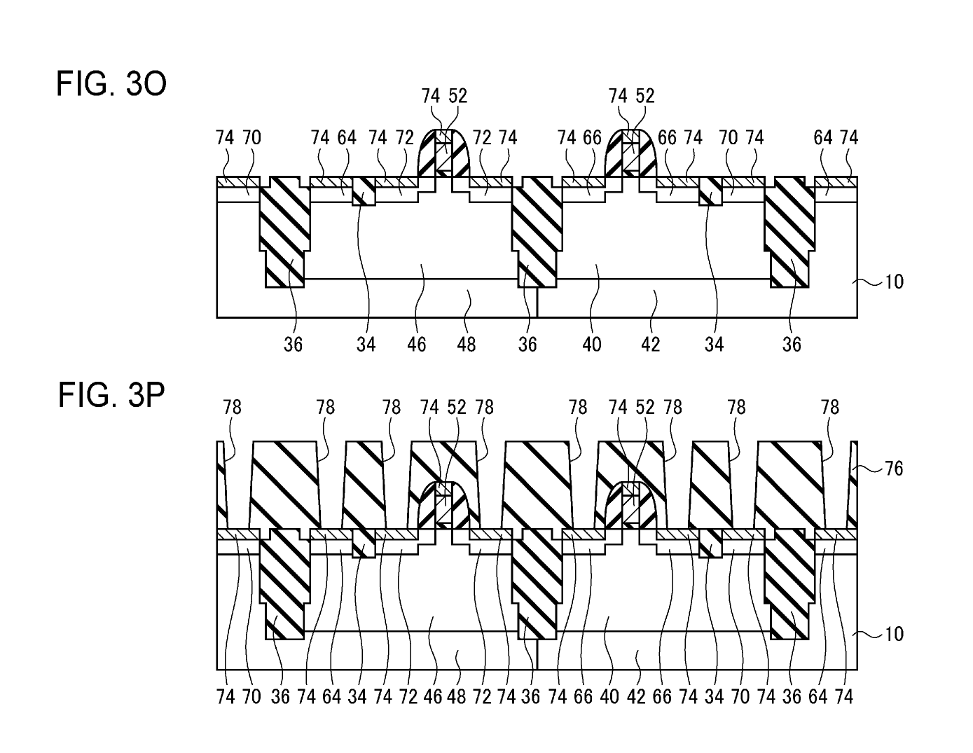

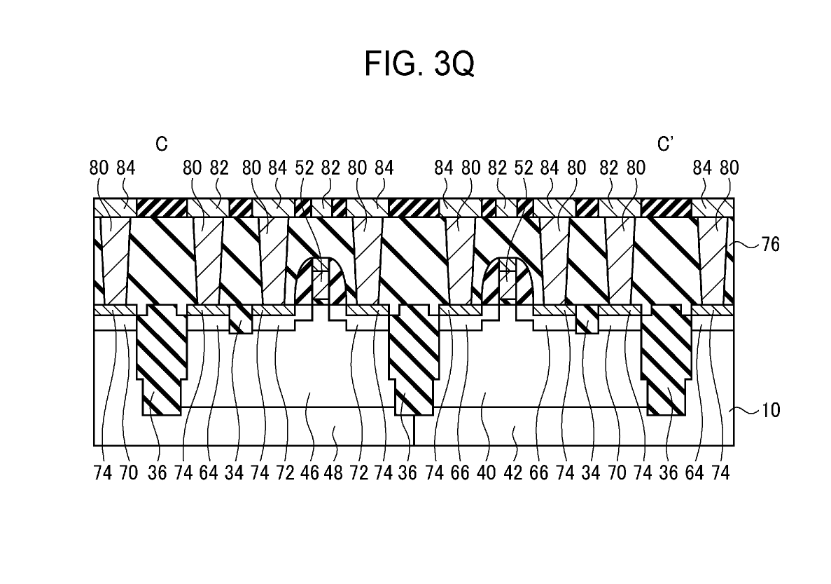

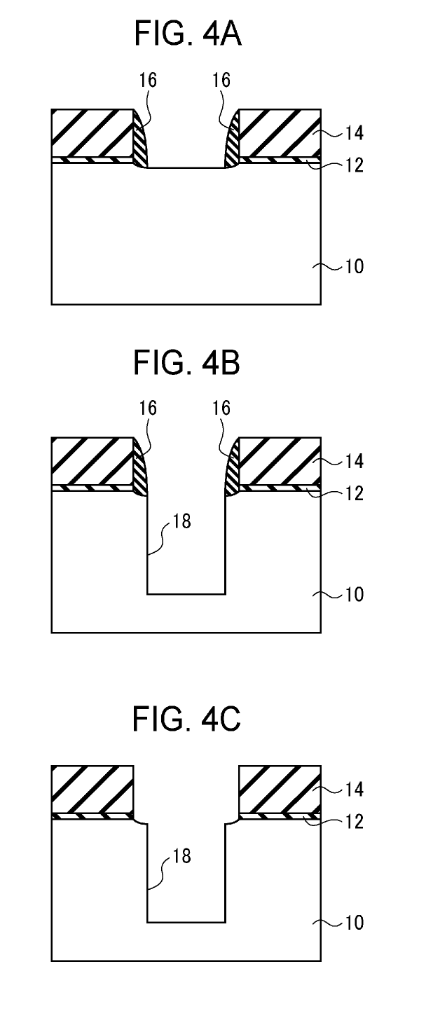

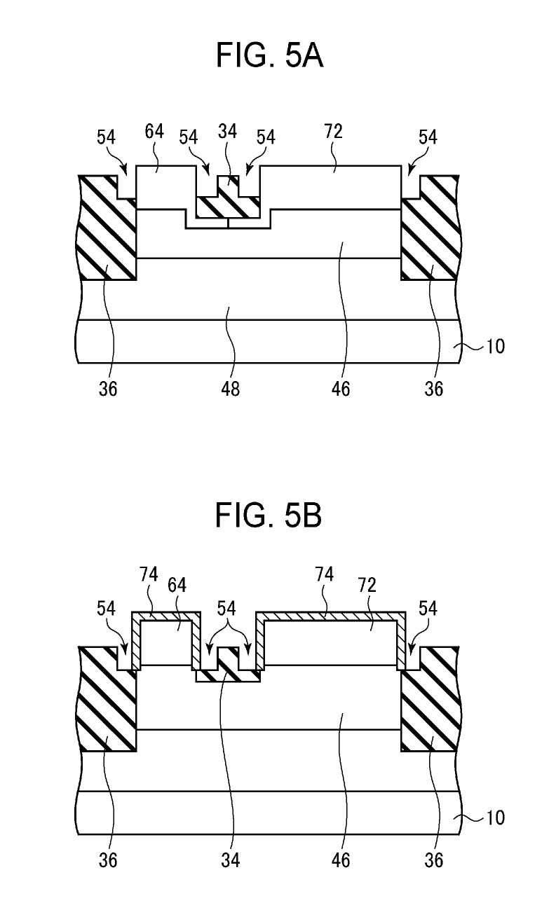

FIG. 1 is a plan view illustrating a structure of the semiconductor device according to the present embodiment. FIGS. 2A and 2B are diagrammatic cross-sectional views illustrating the structure of the semiconductor device according to the present embodiment. FIGS. 3A-3Q and 4A-4C are cross-sectional views illustrating a method of manufacturing a semiconductor device according to the present embodiment. FIGS. 5A and 5B are cross-sectional views explaining the problems caused when the recess is formed on the peripheral surface of the device isolation insulating film.

First, the structure of the semiconductor device according to the present embodiment will be described with reference to FIGS. 1 to 2B. FIG. 2A is the A-A′ line cross-sectional view of FIG. 1, and FIG. 2B is the B-B′ line cross-sectional view of FIG. 1.

A deep device isolation insulating film 36 defining active regions 36a for forming transistors is formed in a silicon substrate 10. A shallow device isolation insulating film 34 defining active regions 34a, 34b in the active regions 36a is formed in the active regions 36a. In FIG. 1, the active region 36a on the right side is for a p-channel transistor forming region, and the active region 34a on the left side is for an n-channel transistor forming region.

A p-well 46 which is deeper than the bottom of the device isolation insulating film 34 and shallower than the bottom of the device isolation insulating film 36 is formed in the n-channel transistor forming region in the silicon substrate 10. An n-well 48 is formed below the p-well 46 in contact with the device isolation insulating film 36. Thus, the p-well 46 formed in the n-channel transistor forming region is electrically isolated from the rest p-wells not illustrated by the n-well 48 and the device isolation insulating film 36.

A gate electrode 52 is formed above the active region 34a of the n-channel transistor forming region with a gate insulating film 50 interposed therebetween. Source/drain regions 72 are formed in the active region 34a on both sides of the gate electrode 52. A p-type impurity region 64 electrically connected to the body region below the gate electrode 52 via the p-well 46 is formed in the surface of the active region 34b of the n-channel transistor forming region. The p-type impurity region 64 is the body contact layer for the connection to the body region of the n-channel transistor.

An n-well 40 which is deeper than the bottom of the device isolation insulating film 34 and shallower than the bottom of the device isolation insulating film 36 is formed in the p-channel transistor forming region in the silicon substrate 10. A p-well 42 is formed below the n-well 40 in contact with the device isolation insulating film 36. Thus, the n-well 40 formed in the p-channel transistor forming region is electrically isolated from the rest n-wells not illustrated by the p-well 42 and the device isolation insulating film 36.

A gate electrode 52 is formed above the active region 34a of the p-channel transistor forming region with a gate insulating film 50 interposed therebetween. Source/drain regions 66 are formed in the active region 34a on both sides of the gate electrode 52. An n-type impurity region 70 electrically connected to the body region below the gate electrode 52 via the n-well 40 is formed in the surface of the active region 34b of the p-channel transistor forming region. The n-type impurity region 70 is the body contact layer for the connection to the body region of the n-channel transistor.

The cross-section of the gate electrode 52 of the n-channel transistor is the same as the B-B′ line cross-section of the p-channel transistor illustrated in FIG. 2B.

Metal silicide layers 74 are formed on the gate electrodes 52, the source/drain regions 66, 72.

An inter-layer insulating film 76 is formed above the silicon substrate 10 with the n-channel transistor and the p-channel transistor formed on. Contact plugs 80 are buried in the inter-layer insulating film 76, connected to the metal silicide layer 74 formed on the electrodes of the transistors.

An interconnection 82 connecting the gate electrode 52 and the p-type impurity region 64 of the n-channel transistor via the contact plugs 80 is formed above the inter-layer insulating film 76. An interconnection 82 connecting the gate electrode 52 and the n-type impurity region 70 of the p-channel transistor via the contact plugs 80 is also formed above the inter-layer insulating film 76. Interconnections 84 connected to the source/drain regions 66, 72 via the contact plugs 80 are also formed above the inter-layer insulating film 76.

Thus, the semiconductor device according to the present embodiment is constituted.

Next, the method of manufacturing the semiconductor device according to the present embodiment will be described with reference to FIGS. 3A to 4C. FIGS. 3A-3Q are the C-C′ line cross-sectional views of FIG. 1, and FIGS. 4A-4C are enlarged views of a device isolation trench forming region.

First, a silicon oxide film 12 of, e.g., an about 5 nm-10 nm thickness is formed above the silicon substrate 10 by, e.g., thermal oxidation method. The oxidation temperature is set to, e.g., 850° C.-1000° C.

Then, a silicon nitride film 14 of, e.g., an about 60 nm-100 nm thickness is formed above the silicon oxide film 12 by, e.g., LPCVD method. The growth temperature of the silicon nitride film 14 is set to, e.g., 700° C.-800° C. (FIG. 3A).

Then, the silicon nitride film 14 and the silicon oxide film 12 are patterned by photolithography and dry etching to remove the silicon nitride film 14 and the silicon oxide film 12 in the device isolation insulating films 34, 36 forming regions.

At this time, the silicon nitride film 14 and the silicon oxide film 12 are etched under the conditions for depositing the reaction product to form a sidewall deposited film 16 of an about 10 nm-20 nm width on the side walls of the patterned silicon nitride film 14 and the silicon oxide film 12 (FIGS. 3B and 4A).

For example, the sidewall deposited film 16 can be formed on the side walls of the patterned silicon nitride film 14 and the silicon oxide film 12 by dry etching under a weak bias voltage and with a mixed gas of a fluorocarbon-based gas, oxygen and an inert gas. The fluorocarbon-based gas is the gas for forming the sidewall deposited film 16. The fluorocarbon-based polymer generated by the reaction of the fluorocarbon-based gas is deposited on the side walls to be the sidewall deposited film 16. The oxygen and the inert gas are for removing the reaction product deposited on the bottom surfaces. The fluorocarbon-based gas can be a gas expressed by CHₐF_{b} or CₓF_{y}, e.g., CF₄, CHF₃, CH₂F₂, CH₃F, C₃F₆, C₄F₃, C₄FE, CsF₃ or others. The inert gas can be Ar, Xe, Kr, N or others.

The configuration of the side walls of the silicon nitride film 14 and the silicon oxide film 12 after patterned is as exemplified in FIG. 4A. The surface of the silicon substrate 10 is a little etched by the etching for removing the reactive product deposited on the bottom surfaces.

The mask film to be used in patterning the silicon nitride film 14 and the silicon oxide film 12 is not specially limited and can be a tri-level mask film of, e.g., a lower layer resist, an intermediate layer of TEOS or others and an upper layer resist.

Next, the silicon substrate 10 is dry etched with the silicon nitride film 14 and the sidewall deposited film 16 as the mask to form the device isolation trenches 18 of, e.g., a 100 nm-200 nm depth in the device isolation insulating films 34, 36 forming regions of the silicon substrate 10 (FIGS. 3C and 4B).

Then, the sidewall deposited film 16 is removed by, e.g., the wet rinse using hydrofluoric acid aqueous solution or others (FIG. 4C). Thus, in the opening in the silicon nitride film 14, an offset portion including a part of the surface of the silicon substrate 10 is formed. The width of the offset portion corresponds to the film thickness of the sidewall deposited film 16.

Next, a photoresist film 24 exposing the deep device isolation insulating film 36 forming region and covering the shallow device isolation insulating film 34 forming region for isolating the active regions 34a and the active regions 34b is formed by photolithography (FIG. 3D).

Then, the silicon substrate 10 is dry etched with the photoresist film 24 and the silicon nitride film 14 as the mask to further dig down the device isolation trench in the deep device isolation insulating film 36 forming region. Thus, the device isolation trench 28 of, e.g., a 250 nm-350 nm depth are formed in the deep device isolation insulating film 36 forming region of the silicon substrate 10. At this time, steps 30 are formed on the side walls of the device isolation trench 28, because of the difference of the opening width between the silicon nitride film 14 and the trench 18 (FIG. 3E).

Next, the photoresist film 24 is removed by, e.g., ashing method.

Thus, the device isolation trenches 18 are formed in the shallow device isolation insulating film 34 forming regions of the silicon substrate 10, and in the deep device isolation insulating film 36 forming region of the silicon substrate 10, the device isolation trench 28 is formed (FIG. 3F).

Next, wet rinse with hydrofluoric acid aqueous solution, for example, is made.

Then, a silicon oxide film as a liner film (not illustrated) is formed on the inside surfaces of the device isolation trenches 18, 28 by, e.g., thermal oxidation method. This thermal oxidation process also has the effect of rounding the corners on the surface of the silicon substrate 10 in the device isolation trenches 18, 28.

Next, a silicon oxide film 32 of a film thickness sufficient to fill the device isolation trenches 18, 28 is deposited above the entire surface by, e.g., high density plasma CVD method (FIG. 3G).

Then, the silicon oxide film 32 above the silicon nitride film 14 is removed by, e.g., CMP (Chemical Mechanical Polishing) method.

Thus, the shallow device isolation insulating film 34 formed of the silicon oxide film 32 and buried in the device isolation trench 18 and the deep device isolation insulating film 36 formed of the silicon oxide film 32 and buried in the device isolation trench 28 are formed by the so-called STI (Shallow Trench Isolation) method.

Thus, active regions 36a are defined by the device isolation insulating film 36. Active regions 34a and active regions 34b are defined by the device isolation insulating film 34.

The thus formed device isolation insulating film 34 has extension 38 extending over the surface of the silicon substrate 10 (the offset portion) due to the difference of the opening width between the device isolation trench 18 and the silicon nitride film 14. (FIG. 3H).

Next, the surfaces of the device isolation insulating films 34, 36 are etched by a prescribed amount with the silicon nitride film 14 as the mask by, e.g., wet etching with hydrofluoric acid aqueous solution. This etching is for adjusting the height of the surface of the active regions and the height of the surfaces of the device isolation insulating films 34, 36 to be substantially the same in the completed transistor.

Then, the silicon nitride film 14 is removed by, e.g., wet etching with hot phosphoric acid.

Next, the silicon oxide film 12 is removed by, e.g., wet etching with hydrofluoric acid aqueous solution (FIG. 3I).

Then, a silicon oxide film (not illustrated) to be the protection film for ion implantation is formed above the surface of the silicon substrate 10 by, e.g., thermal oxidation method.

Next, a photoresist film (not illustrated) covering the n-channel transistor forming region and exposing the p-channel transistor forming region is formed by photolithography.

Then, the ion implantation is made with this photoresist film as the mask to form the n-well 40 and the p-well 42. The n-well 40 is formed in a region which is deeper than the bottom of the device isolation insulating film 34 and shallower than the bottom of the device isolation insulating film 36. The p-well 42 is formed in contact with the device isolation insulating film 36 in a region deeper than the n-well 40. Thus, the n-wells 40 formed in the respective transistor regions are electrically isolated by the p-wells 42 and the device isolation insulating film 36.

The n-well 40 is formed by ion implanting, e.g., phosphorus ions (P⁺) under the conditions of a 70 keV-120 keV acceleration energy and a 5×10¹² cm⁻²-3×10¹³ cm⁻² dose or arsenic ions (As⁺) under the conditions of a 100 keV-250 keV acceleration energy and a 5×10¹² cm⁻²-3×10¹³ cm⁻² dose. At this time both phosphorus ions and arsenic ions may be ion implanted to form the n-well. The p-well 42 is formed by ion implanting, e.g., boron ions (B⁺) under the conditions of a 100 keV-200 keV acceleration energy and a 7×10¹² cm⁻²-3×10¹³ cm⁻² dose.

Then, the photoresist film used in forming the n-well 40 and the p-well 42 is removed by, e.g., ashing method.

Next, a photoresist film 44 covering the p-channel transistor forming region and exposing the n-channel transistor forming region is formed by photolithography.

Next, ion implantation is made with the photoresist film as the mask to form the p-well 46 and the n-well 48 (FIG. 3J). The p-well 46 is formed in a region which is deeper than the bottom of the device isolation insulating film 34 and shallower than the bottom of the device isolation insulating film 36. The n-well 48 is formed in contact with the device isolation insulating film 36 in a region deeper than the p-well 46. Thus, the p-wells 46 formed in the respective transistor regions are electrically isolated by the n-wells 48 and the device isolation insulating film 36.

The p-well 46 is formed by ion implanting, e.g., boron ions under the conditions of a 20 keV-50 keV acceleration energy and a 5×10¹² cm⁻²-3×10¹³ cm⁻² dose. The n-well 48 is formed by ion implanting, e.g., arsenic ions under the conditions of a 200 keV-400 keV acceleration energy and a 7×10¹² cm⁻²-3×10³ cm⁻² dose.

1 Then, the photoresist film 44 is removed by, e.g., ashing method.

Next, thermal processing is made in an inert gas atmosphere to activate the implanted impurities. For example, rapid thermal processing of 3 seconds-10 seconds and 900° C.-1100° C. is made in nitrogen atmosphere.

Then, the silicon oxide film (not illustrated) as the protection film is removed by, e.g., wet etching with hydrofluoric acid aqueous solution.

In the step of the wet etching for removing the silicon oxide film 12, the silicon oxide film as the protection film, etc., the device isolation insulating films 34, 36 are isotropically etched. At this time, at the parts thereof projected beyond the surface of the silicon substrate 10, the etching advances also from the side surfaces, and resultantly, on the peripheral surface of the device isolation insulating film 36, recesses 54 lower than the surface of the silicon substrate 10 are formed. In the device isolation insulating film 34, however, the extensions 38 extending over the silicon substrate 10 is provide, whereby the formation of recesses on the peripheral surfaces can be suppressed.

For suppressing the formation of the recesses on the peripheral surfaces, it is preferable that the width of the offset portions are suitably set so that the width of the extensions 38 of the device isolation insulating film 34 is larger than the total etching amount of the etching to be made after the device isolation insulating films 34, 36 are formed. The width of the offset portions can be controlled by the film thickness of the sidewall deposited film 16.

Then, the surface of the silicon substrate 10 is thermally oxidized at a temperature of, e.g., 750° C.-1100° C. to form the gate insulating film 50 of silicon oxide film.

Next, a polycrystalline silicon film is deposited above the gate insulating film 50 by, e.g., LPCVD method.

Next, the polycrystalline silicon film is patterned by photolithography and dry etching to form the gate electrodes 50 of the polycrystalline silicon film (FIG. 3K).

Next, a photoresist film (not illustrated) covering the active regions 34b of the n-channel transistor forming region and the p-channel transistor forming region and exposing the active region 34a of the p-channel transistor forming region is formed by photolithography.

Next, ion implantation is made with this photoresist film and the gate electrodes 52 as the mask to form the p-type impurity regions 56 to be the extension regions. As required, the n-type pocket regions may be formed together with the p-type impurity regions 56.

Next, the photoresist film used in forming the p-type impurity regions 56 is removed by, e.g., ashing method.

Then, a photoresist film 58 covering the active regions 34b of the p-channel transistor forming region and the n-channel transistor forming region 34 and exposing the active region 34a of the n-channel transistor forming region is formed by photolithography.

Next, ion implantation is made with the photoresist film 58 and the gate electrodes 52 as the mask to form the n-type impurity regions 60 to be the extension regions (FIG. 3L). As required, the p-type pocket regions may be formed together with the n-type impurity regions 60.

Next, the photoresist film 58 is removed by, e.g., ashing method.

Next, a silicon oxide film is deposited above the entire surface by, e.g., CVD method. As processing conditions, the temperature is, e.g., 400° C.-600° C. In place of the silicon oxide film, a silicon nitride film may be deposited.

Then, the silicon oxide film deposited above the entire surface is anisotropically etched to be left selectively on the side walls of the gate electrodes 52. Thus, the sidewall spacers 62 of the silicon oxide film are formed (FIG. 3M).

Then, a photoresist film (not illustrated) exposing the active region 34a of the p-channel transistor forming region, the active region 34b of the n-channel transistor forming region and the contact region of the p-well 42 and covering the rest region is formed.

Next, ion implantation is made with this photoresist film, the gate electrodes 52 and the sidewall spacers 62 as the mask. Thus, the p-type impurity regions 64 to form the source/drain regions 66 together with the p-type impurity regions 56 are formed in the active region 34a of the p-channel transistor forming region. The p-type impurity region 64 to be the body contact region is formed in the active region 34b of the n-channel transistor forming region. The p-type impurity region 64 is formed in the contact region of the p-well 42.

Next, the photoresist film used as the mask in forming the p-type impurity regions 64 is removed by, e.g., ashing method.

Next, a photoresist film 68 exposing the active region 34a of the n-channel transistor forming region, the active region 34b of the p-channel transistor forming region and the contact region of the n-well 48 and covering the rest region is formed.

Then, ion implantation is made with the photoresist film 68, the gate electrodes 52 and the sidewall spacers 62 as the mask. Thus, the n-type impurity regions 70 to form the source/drain regions 72 together with the n-type impurity regions 60 are formed in the active region 34a of the n-channel transistor forming region. The n-type impurity region 70 to be the body contact region is formed in the active region 34b of the p-channel transistor forming region. The n-type impurity region 70 is formed in the contact region of the n-well 48 (FIG. 3N).

Then, the photoresist film 68 is removed by, e.g., ashing method.

Then, thermal processing is made in an inert gas atmosphere to activate the implanted impurities. For example, the spike annealing of 900° C.-1100° C. is made in nitrogen atmosphere.

Next, by the self-aligned silicide (SALISIDE) process, the metal silicide layers 74 are formed selectively on the source/drain regions 66, 72, the p-type impurity regions 62, the n-type impurity regions 70 and the gate electrodes 52. As the metal material for forming the metal silicide layers 74, titanium (Ti), cobalt (Co), nickel (Ni) or others, for example, may be used.

Thus, the n-channel transistor including the gate electrode 52 and the source/drain regions 72, and the p-channel transistor including the gate electrode 52 and the source/drain regions 66 are formed on the silicon substrate 10 (FIG. 3O).

Next, an insulating film of silicon oxide film or others is deposited above the silicon substrate 10 with the n-channel transistor and the p-channel transistor formed on by, e.g., CVD method to form the inter-layer insulating film 76.

Next, the surface of the inter-layer insulating film 76 is planarized by, e.g., CMP method.

Then, the contact holes 78 reaching down to the metal silicide layers 74 formed on the respective electrodes of the n-channel transistor and the p-channel transistor are formed by photolithography and dry etching (FIG. 3P).

Then, the contact plugs 80 containing, e.g., a barrier metal and tungsten film are formed in the contact holes 78.

Next, the interconnections 82 for electrically connecting the gate electrodes 52 and the body contact regions 34b via the contact plugs 80 are formed on the inter-layer insulating film 76 with the contact plugs 80 buried in. Also the interconnections 84 connected to the source/drain regions 66, 72, the p-type impurity regions 64, the n-type impurity regions 70 via the contact plugs 80, etc. are formed (FIG. 3Q).

Hereafter, a prescribed backend processing is made, and the semiconductor device according to the present embodiment is completed.

As described above, in the method of manufacturing the semiconductor device according to the present embodiment, the device isolation insulating film 34 is formed extended over the surface of the silicon substrate 10 so that the recesses 54 are not formed on the peripheral surfaces of the shallow device isolation insulating film 34. This is for the following reason.

Firstly, with the device isolation insulating film 34 having the film thickness reduced by the recesses 54 formed, the impurities implanted for forming the source/drain regions and the contact regions often penetrate the device isolation insulating film 34. For example, when the impurity for forming the n-type source/drain regions 72 penetrates the device isolation insulating film 34, the n-type source/drain regions 72 and the p-type impurity region 64 contact with each other below the device isolation insulating film 34 (FIG. 5A). The n-type source/drain regions 72 and the p-type impurity region 64 are highly doped impurity regions, and when such highly doped impurity regions form the p-n junction, leakage current is generated by the band-to-band tunnel current. This is the same with the p-channel transistor.

Secondly, with the edges of the active regions exposed due to the recesses 54 formed on the device isolation insulating film 34, often the metal silicide layer 74 is formed at the exposed edge of the active region. When the metal silicide layer 74 directly contacts the p-well 46 beyond the n-type source/drain region 72, the metal silicide layer 74 formed on the n-type source/drain region 72 is connected to the p-type impurity region 64 via the p-well 46, which causes leakage current. This is the same with the p-channel transistor (FIG. 5B).

As described above, the recesses 54 formed on the peripheral surfaces of the shallow device isolation insulating film 34 are a cause for various leakage currents.

In the method of manufacturing the semiconductor device according to the present embodiment, however, the device isolation insulating film 34 is formed, extended over the surface of the silicon substrate 10, whereby the formation of the recesses 54 on the peripheral surfaces of the device isolation insulating film 34 in the later etching steps is suppressed. Thus, the penetration of the implanted impurities and the formation of the metal silicide layer 74 at the exposed edges of the active regions can be suppressed, whereby the leakage current can be reduced.

As described above, according to the present embodiment, the formation of the recesses on the peripheral surfaces of the device isolation insulating film can be prevented, whereby the leakage current can be reduced, and the semiconductor device of low electric power consumption can be realized.

### A Second Embodiment

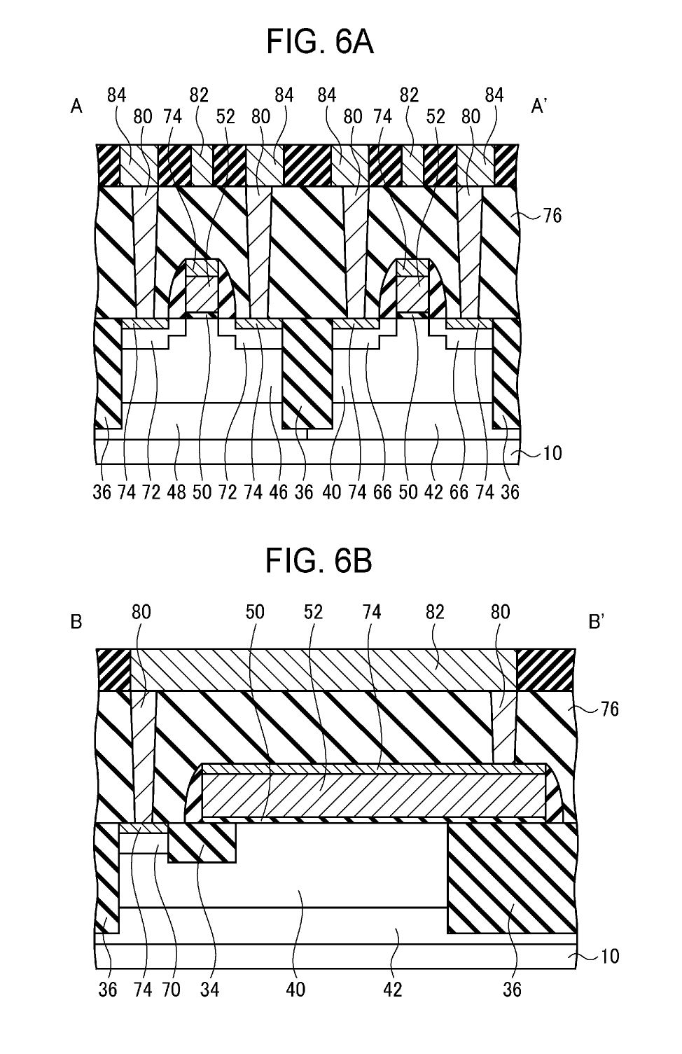

A semiconductor device and a method of manufacturing the semiconductor device according to a second embodiment will be described with reference to FIGS. 6A to 8D. The same members of the present embodiment as those of the semiconductor device and the method of manufacturing the same according to the first embodiment illustrated in FIGS. 1 to 5B are represented by the same reference numbers not to repeat or to simplify the description.

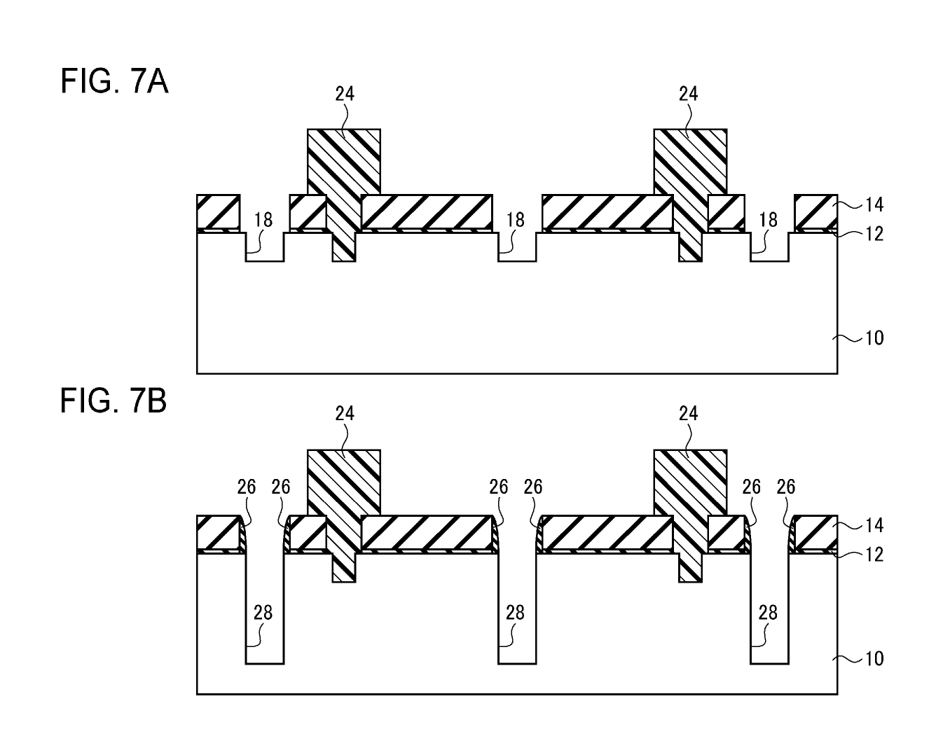

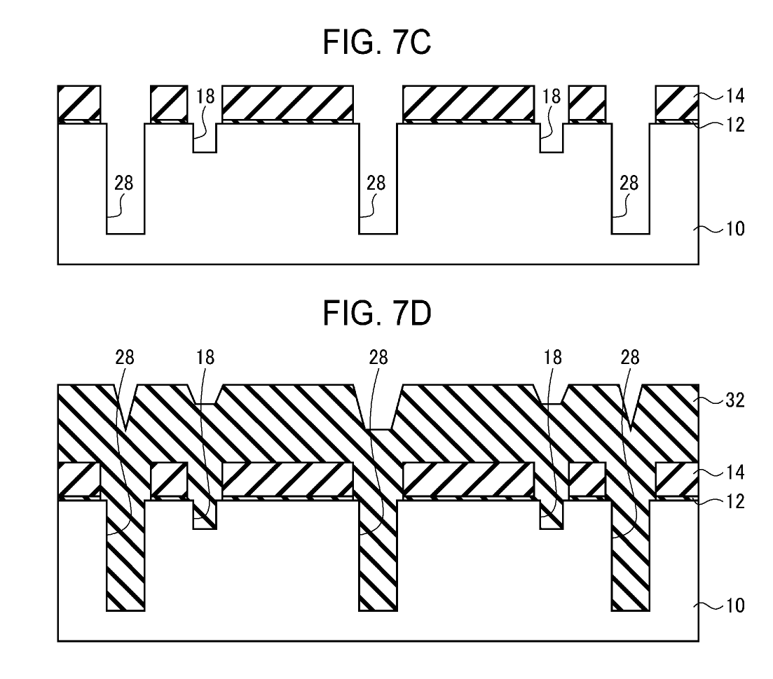

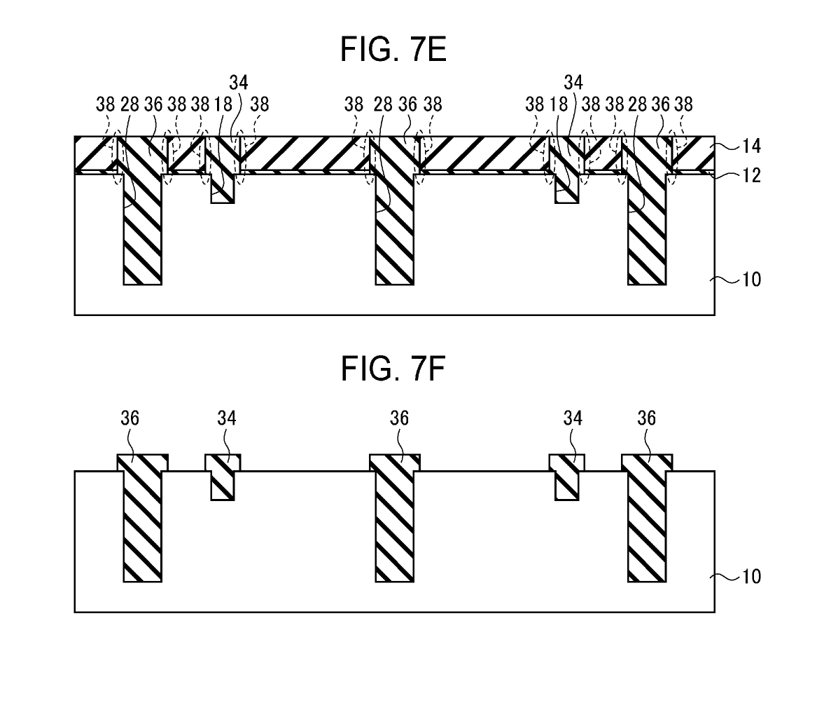

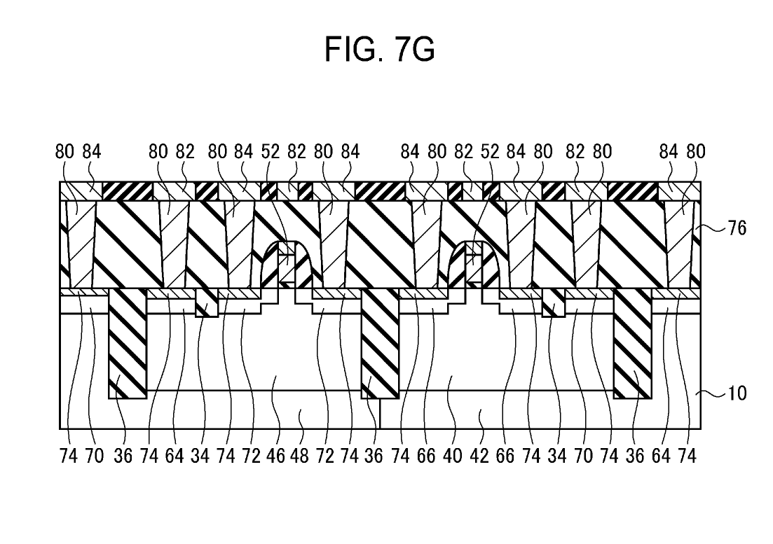

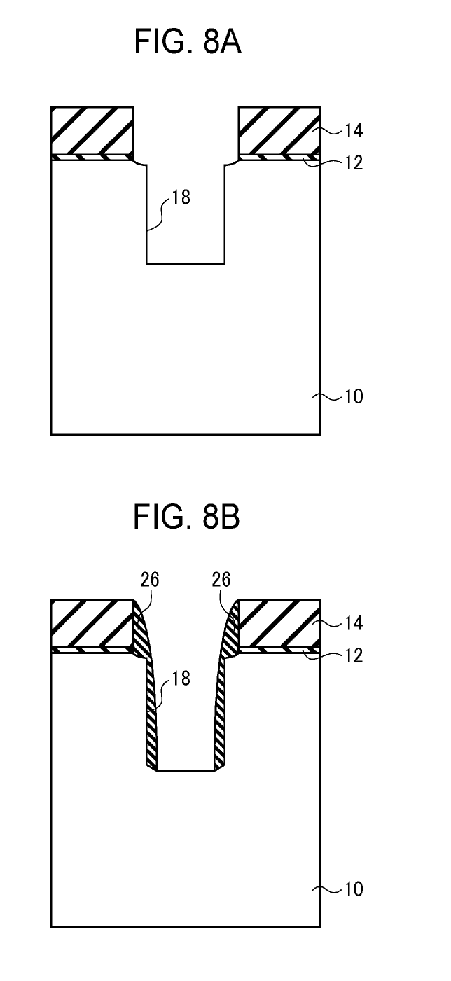

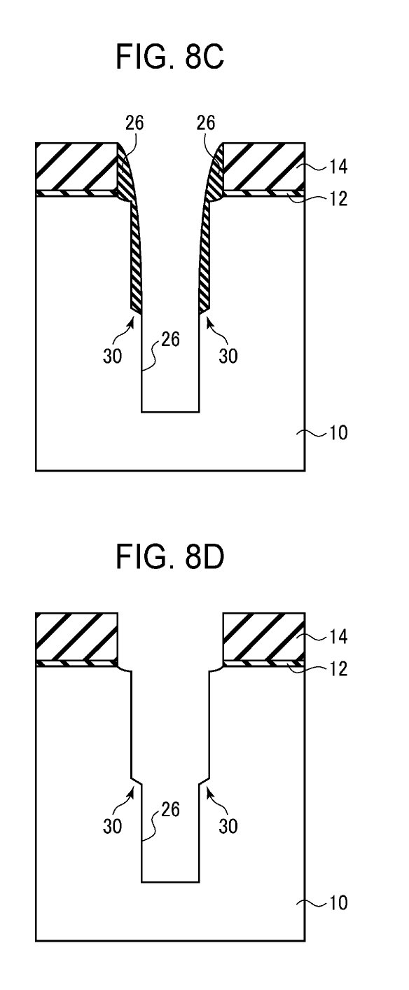

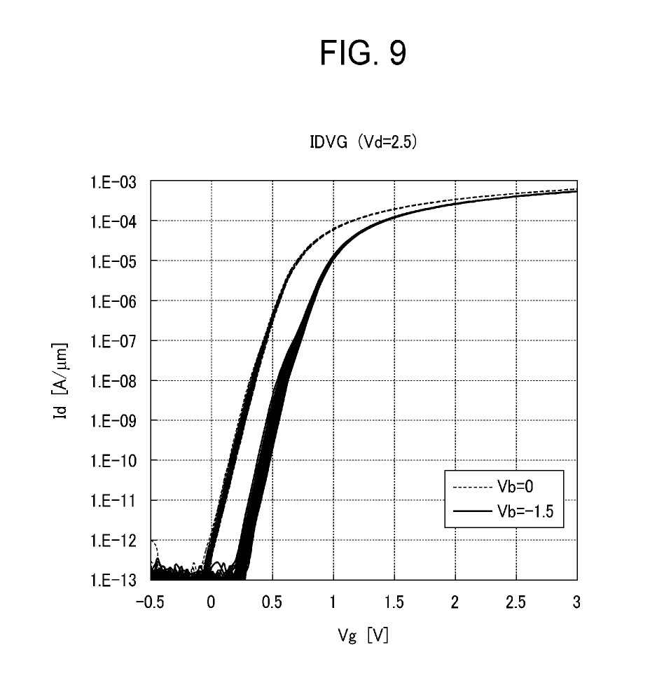

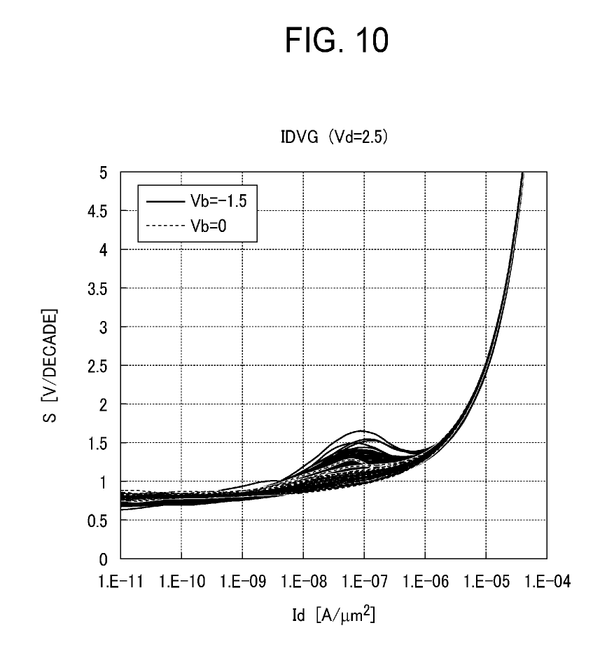

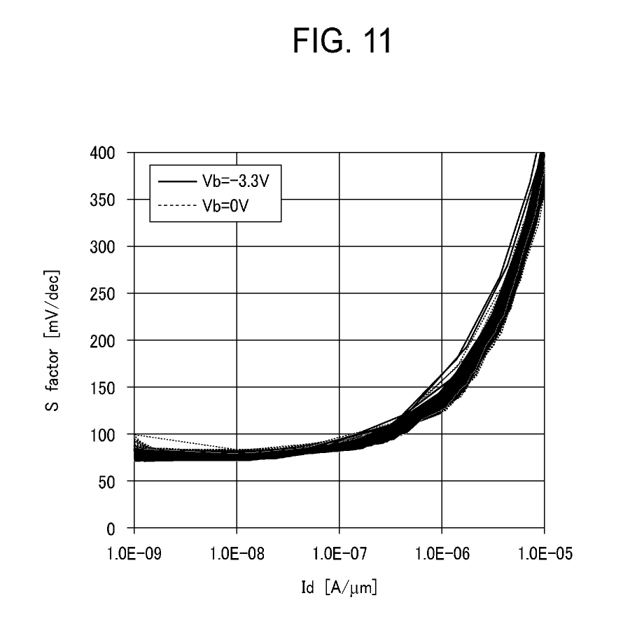

FIGS. 6A and 6B are diagrammatic cross-sectional views illustrating the structure of the semiconductor device according to the present embodiment. FIGS. 7A-7G and FIGS. 8A-8D are cross-sectional views illustrating the method of manufacturing the semiconductor device according to the present embodiment. FIGS. 9 and 10 are graphs illustrating the subthreshold characteristics of the n-channel transistor manufactured by using a device isolation insulating film without extension. FIG. 11 is a graph illustrating the subthreshold characteristics of the n-channel transistor manufactured by using a device isolation insulating film with extension.

First, the structure of the semiconductor device according to the present embodiment will be described with reference to FIGS. 6A and 6B. FIG. 6A is the A-A′ line cross-sectional view of FIG. 1, and FIG. 6B is the B-B′ line cross-sectional view of FIG. 1.

The semiconductor device according to the present embodiment is the same as the semiconductor device according to the first embodiment except that as illustrated in FIGS. 6A and 6B, the recesses 54 are not formed on the peripheral surfaces of the deep device isolation insulating film 36 either.

As illustrated in FIG. 6B, the gate electrode 52 is formed not only on the device isolation insulating film 34 but also on the device isolation insulating film 36. At this time, when the recesses are formed on the peripheral surfaces of the device isolation insulating films 34, 36, often the gate electrode 52 is formed, covering the corner of the active region along the configuration of the recess. When the gate electrode 52 is formed, covering the corner of the active region, field concentration takes place at the corner of the active region, which often causes characteristics fluctuations, such as variations of the threshold voltage.

The formation of the recesses on the peripheral surfaces of not only the device isolation insulating film 34 but also the device isolation insulating film 36 can be suppressed, whereby characteristics fluctuations of the transistor can be suppressed.

Then, the method of manufacturing the semiconductor device according to the present embodiment will be described with reference to FIGS. 7A-7G and 8A-8D. FIGS. 7A-7G are the C-C′ line cross-sectional views of FIG. 1, and FIGS. 8A-8D are enlarged sectional views of the device isolation trench forming region.

First, in the same way as in the method of manufacturing the semiconductor device according to the first embodiment illustrated in FIGS. 3A to 3D, the device isolation trench 18 and the photoresist film 24 are formed (FIG. 7A and FIG. 8A).

Then, processing is made under the same etching conditions for the silicon nitride film 14 as in the step of FIG. 3B to deposit the sidewall deposited film 26 on the side walls of the silicon nitride film 14 and the device isolation trench 18 (FIG. 8B). At this time, the silicon nitride film 14 is a little etched, but the sidewall deposited film 26 deposited retain the side wall configurations of the silicon nitride film 14 and the device isolation trenches 18. For further ensuring the protection of the side wall configurations, it is preferable that the sidewall deposited film 26 is formed, covering the corners of the offset portions of the surface of the silicon substrate 10.

Then, the silicon substrate 10 is dry etched with the photoresist film 24, the silicon nitride film 14 and the sidewall deposited film 26 as the mask to further dig down the device isolation trenches 18 in the deep device isolation insulating film 36 forming regions. Thus, in the deep device isolation insulating film 36 forming regions, the device isolation trenches 28 of, e.g., a 250 nm-350 nm depth are formed (FIGS. 7B and 8C). At this time, because of the sidewall deposited film 26 formed on the side walls of the device isolation trenches 18, the width of the openings of the device isolation trenches 28 become smaller by the sidewall deposited film 26, and the steps 30 are formed on the side walls of the device isolation trenches 28.

Next, wet rinse with, e.g., hydrofluoric acid aqueous solution is made to remove the sidewall deposited film 26 (FIGS. 7C and 8D).

Next, a silicon oxide film (not illustrated) as the liner film is formed on the inside walls of the device isolation trenches 18, 28 by, e.g., thermal oxidation method. This thermal oxidation step also has the effect of rounding the corners of the surface of the silicon substrate 10 in the device isolation trenches 18, 28.

Next, the silicon oxide film 32 of a film thickness sufficient to fill the device isolation trenches 18, 28 is formed above the entire surface by, e.g., high density plasma CVD method (FIG. 7D).

Next, the silicon oxide film 32 above the silicon nitride film 14 is removed by, e.g., CMP method.

Thus, the shallow device isolation insulating film 34 formed of the silicon oxide film 32 and buried in the device isolation trenches 18, and the deep device isolation insulating film 36 formed of the silicon oxide film 32 and buried in the device isolation trenches 28 are formed by the so-called STI method.

The thus formed device isolation insulating films 34, 36 have the extensions 38 extended over the surface of the silicon substrate 10 due to the difference between the opening width of the device isolation trenches 18, 28 and the opening width of the silicon nitride film (FIG. 7E).

Then, width of the extensions 38 of the device isolation insulating film 34, 36 can be controlled by the film thickness of the sidewall deposited film 16, as in the first embodiment.

Next, the surface of the device isolation insulating films 34, 36 are etched with the silicon nitride film 14 as the mask by a prescribed amount by wet etching with, e.g., hydrofluoric acid aqueous solution. This etching is for adjusting the height of the surface of the active region and the height of the surfaces of the device isolation insulating films 34, 36 to be substantially the same in the completed transistor.

Next, the silicon nitride film 14 is removed by, e.g., wet etching with hot phosphoric acid.

Then, the silicon oxide film 12 is removed by wet etching with, e.g., hydrofluoric acid aqueous solution (FIG. 7F).

Hereafter, in the same way as in the method of manufacturing the semiconductor device according to the first embodiment illustrated in FIGS. 3J to 3Q, the semiconductor device according to the present embodiment is completed (FIG. 7G).

The device isolation insulating films 34, 36 having the extensions 38 can suppress the formation of the recesses 54 on the peripheral surfaces of the device isolation insulating films 34, 36. Thus, the leakage current can be reduced, and the fluctuations of the transistor characteristics can be suppressed.

FIGS. 9 and 10 are graphs of the subthreshold characteristics of an n-channel transistor manufactured by using the device isolation insulating films 34, 36 without the extensions 38. FIG. 11 is a graph of the subthreshold characteristics of the an n-channel transistor manufactured by using the device isolation insulating film 34, 36 having the extensions 38. FIG. 21 is a graph illustrating the Id-Vg characteristic, and FIGS. 10 and 11 are graphs illustrating the relationships between the S parameter and the Id. The Vg indicates a gate voltage, and the Id indicates a drain current.

As illustrated in FIG. 9, in the n-channel transistor formed by using the device isolation insulating films 34, 36 without the extensions 38, humps are observed in the subthreshold region, and it is seen that the fluctuations of the characteristics are large. Especially, when Vb=0 where the back gate bias is shallow, this is conspicuous. In FIG. 10, where the measured result of FIG. 9 is substituted by the relationships between the S parameter and the drain current Id, a distinct peak indicating a hump of the subthreshold region is recognized.

In contrast to this, in the n-channel transistor of the present embodiment manufactured by using the device isolation insulating films 34, 36 having the extensions 38, as illustrated in FIG. 11, no peak is observed in the relationships between the S parameter and the drain current Id, and the fluctuations of the characteristics are small. Based on this result, it has been confirm that in the n-channel transistor of the present embodiment manufactured by using the device isolation insulating films 34, 36 having the extensions 38, the hump and the fluctuations of the characteristics can be suppressed.

As described above, according to the present embodiment, the formation of the recesses on the peripheral surfaces of the device isolation insulating film can be suppressed, whereby the leakage current and the fluctuations of the characteristics can be reduced, and the semiconductor device of high reliability and low power consumption can be realized.

### A Third Embodiment

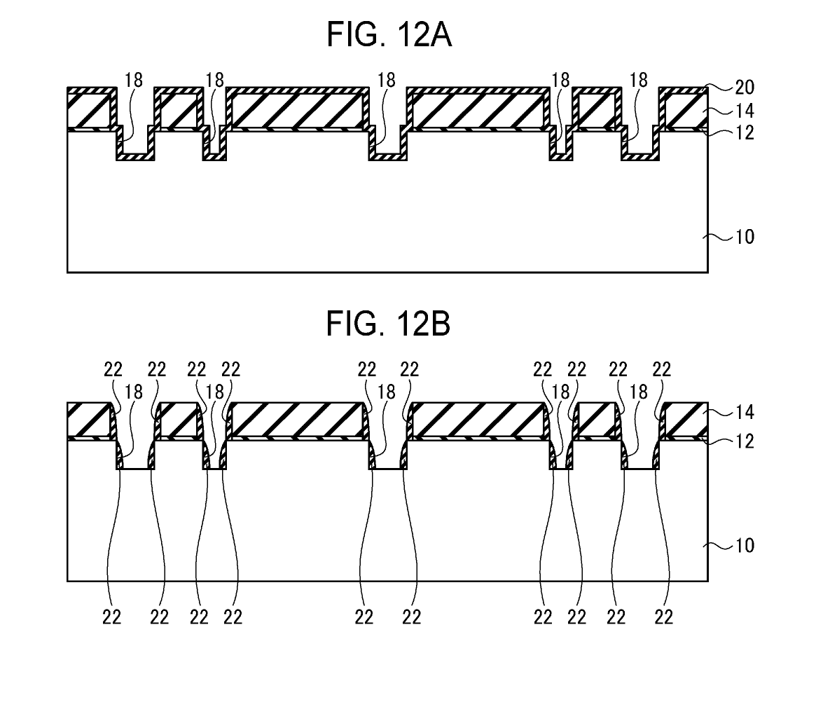

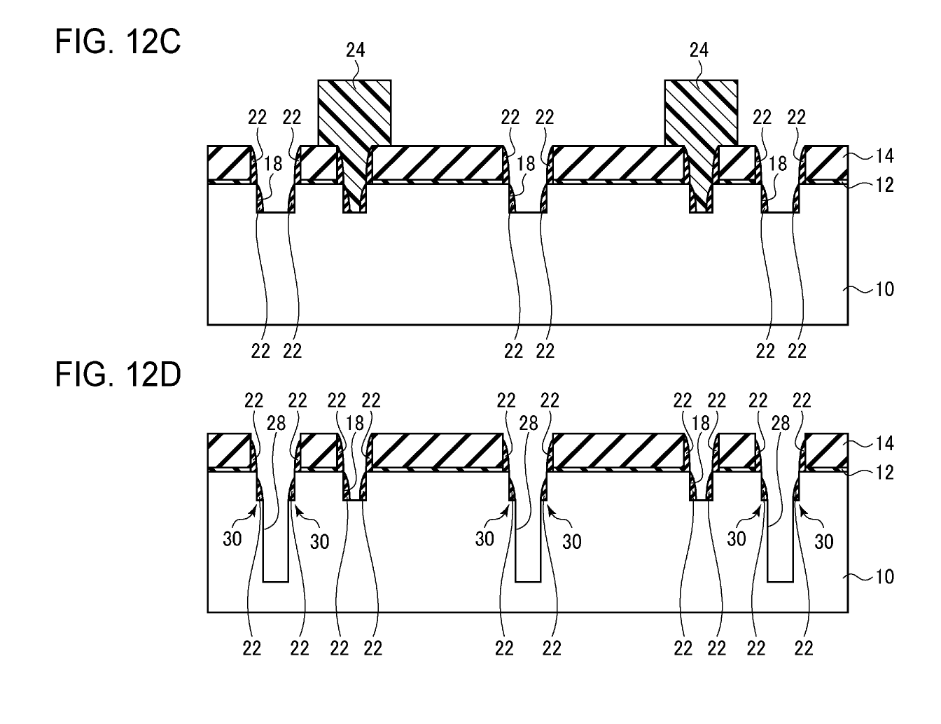

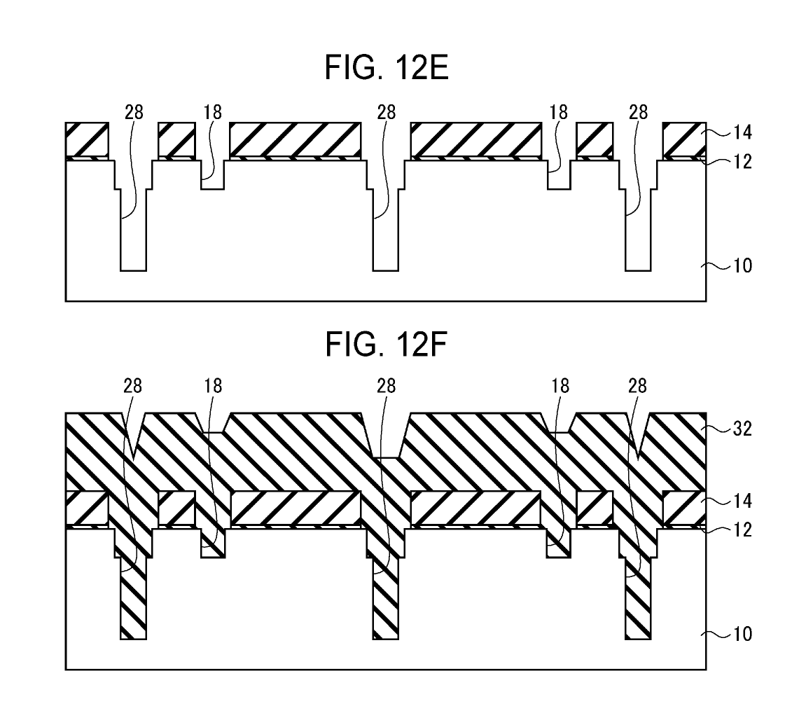

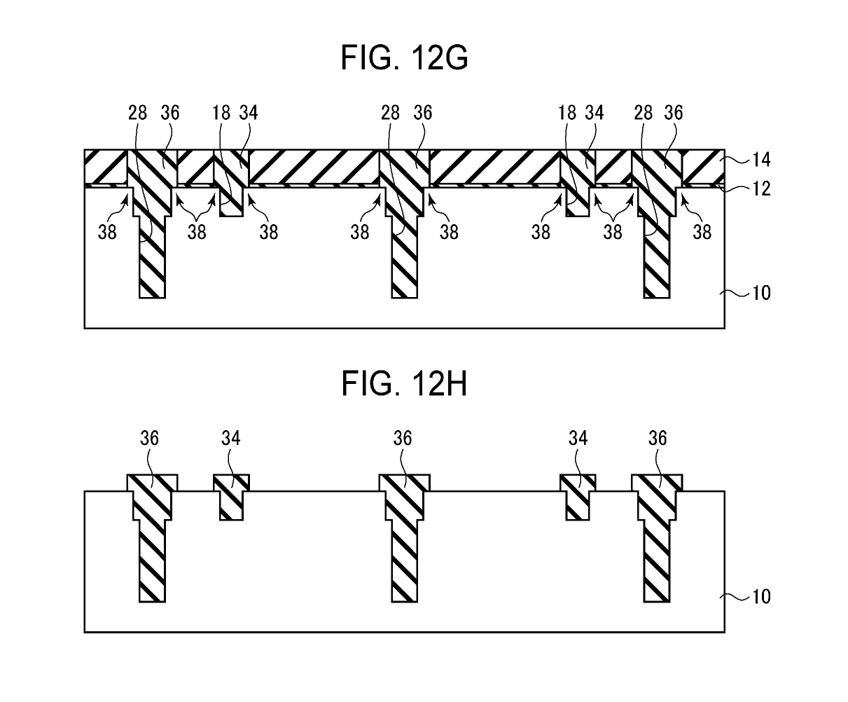

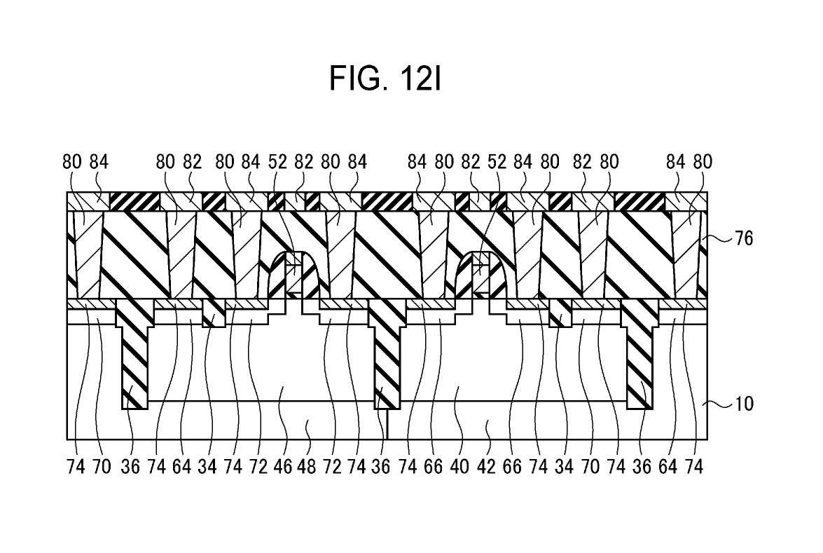

A method of manufacturing a semiconductor device according to a third embodiment will be described with reference to FIGS. 12A-12I. The same members of the present embodiment as those of the semiconductor device and the method of manufacturing the same according to the first and the second embodiment illustrated in FIGS. 1 to 11 are represented by the same reference numbers not to repeat or to simplify the description.

FIGS. 12A-12I are cross-sectional views illustrating the method of manufacturing the semiconductor device according to the present embodiment.

In the present embodiment, another manufacturing method of the semiconductor device according to the second embodiment will be described. FIGS. 12A-12I are the C-C′ line cross-sectional views of FIG. 1.

First, in the same way as in the method of manufacturing the semiconductor device according to the first embodiment illustrated in FIGS. 3A to 3D, the device isolation trenches 18 are formed.

Next, a silicon oxide film of, e.g. a 5 nm-15 nm thickness is deposited above the entire surface by, e.g., CVD method to form the insulating film 20 of the silicon oxide film (FIG. 12A). The insulating film 20 is not limited to the silicon oxide film as long as the film has etching characteristics different from those of silicon, and may be formed of, e.g., silicon nitride film.

Then, the insulating film 20 is etched back to form the sidewall spacers 22 of the insulating film 20 on the side walls of the silicon nitride film 14 and the device isolation trenches 18 (FIG. 12B).

Next, a photoresist film 24 exposing the region for the deep device isolation insulating film 36 and covering the region for the shallow device isolation insulating film 34 separating the active region 34a and the active region 34b is formed by photolithography (FIG. 12C).

Next, the silicon substrate 10 is dry etched with the photoresist film 24, the silicon nitride film 14 and the sidewall spacers 22 as the mask to further dig down the device isolation trenches 18 in the deep device isolation insulating film 36 forming regions. Thus, the device isolation trenches 28 of, e.g. a 250 nm-350 nm depth are formed in the region of the silicon substrate where the deep device isolation insulating film 36 to be formed in. At this time, because of the sidewall spacers 22 formed on the side walls of the device isolation trenches 18, the opening width of the device isolation trenches 28 is decreased by the sidewall spacers 22, and the steps 30 are formed on the side walls of the device isolation trenches 28.

Next, the photoresist film 24 is removed by, e.g., ashing method (FIG. 12D).

Next, the sidewall spacers 22 are removed by, e.g., wet rinse with hydrofluoric acid aqueous solution (FIG. 12E).

Next, a silicon oxide film (not illustrated) as the liner film is formed on the inside walls of the device isolation trenches 18, 28 by, e.g., thermal oxidation method. This thermal oxidation step also has the effect of rounding the corners of the surface of the silicon substrate 10 in the device isolation trenches 18, 28.

Next, the silicon oxide film 32 of a film thickness sufficient to fill the device isolation trenches 18, 28 is deposited above the entire surface by, e.g., high density plasma CVD method (FIG. 12F).

Next, the silicon oxide film 32 above the silicon nitride film 14 is removed by, e.g., CMP method.

Thus, the shallow device isolation insulating film 34 formed of the silicon oxide film 32 and buried in the device isolation trenches 18, and the deep device isolation insulating film 36 formed of the silicon oxide film 32 and buried in the device isolation trenches 28 are formed by the so-called STI method.

The thus formed device isolation insulating films 34, 36 have extensions 38 extended over the surface of the silicon substrate 10 due to the difference between the opening width of the device isolation trenches 18, 28 and the opening width of the silicon nitride film (FIG. 12G).

The width of the extensions 38 of the device isolation insulating films 34, 36 can be controlled by the film thickness of the sidewall deposited film 16, as in the first embodiment.

Then, the surfaces of the device isolation insulating films 34, 36 are etched with the silicon nitride film 14 as the mask by a prescribed amount by wet etching with, e.g., hydrofluoric acid aqueous solution. This etching is for adjusting the height of the surface of the active regions and the height of the surfaces of the device isolation insulating films 34, 36 to be substantially the same in the completed transistor.

Next, the silicon nitride film 14 is removed by, e.g., wet etching with hot phosphoric acid.

Next, the silicon oxide film 12 is removed by, e.g., wet etching with hydrofluoric acid aqueous solution (FIG. 12H).

Hereafter, in the same way as in the method of manufacturing the semiconductor device according to the first embodiment illustrated in FIGS. 3J to 3Q, the semiconductor device according to the present embodiment is completed (FIG. 12I).

The device isolation insulating films 34, 36 having the extensions 38 are formed, whereby the formation of the recesses 54 on the peripheral surfaces of the device isolation insulating film 34, 36 can be suppressed. Consequently, the leakage current is decreased, and the fluctuations of the transistor characteristics can be suppressed.

As described above, according to the present embodiment, the formation of the recesses on the peripheral surfaces of the device isolation insulating films can be suppressed, whereby the leakage current and fluctuations of the characteristics can be reduced, and the semiconductor device of high reliability and low power consumption can be realized.

### A Fourth Embodiment

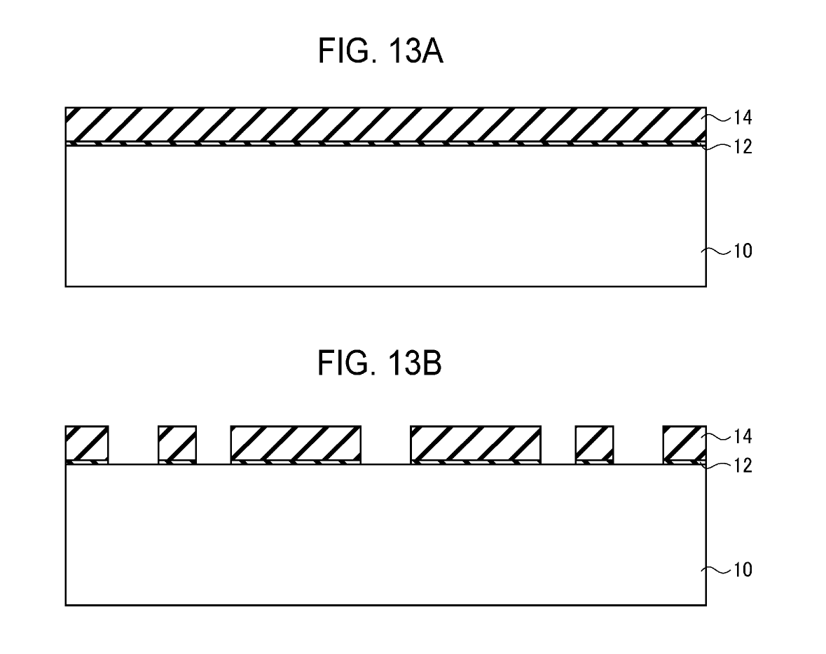

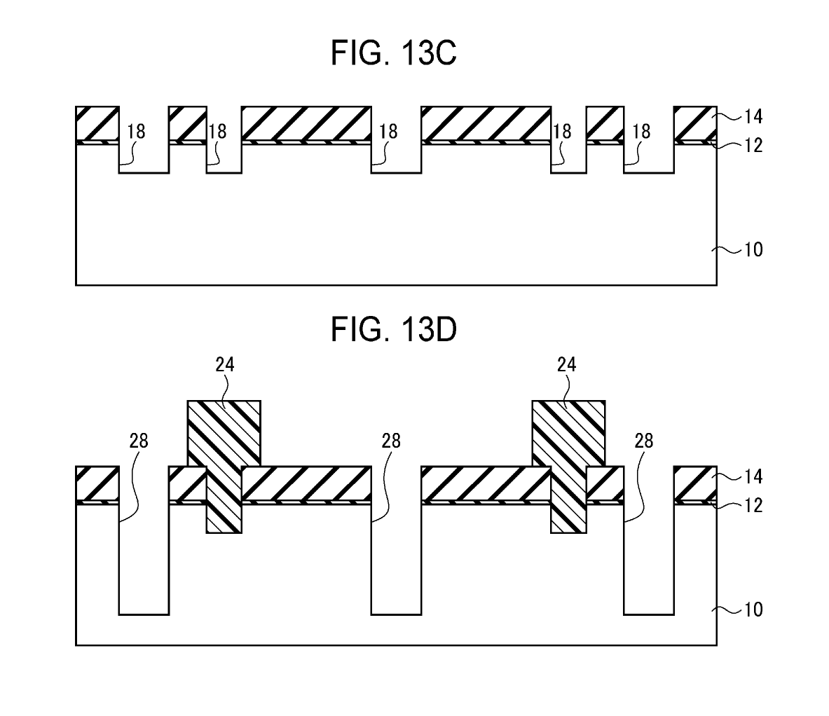

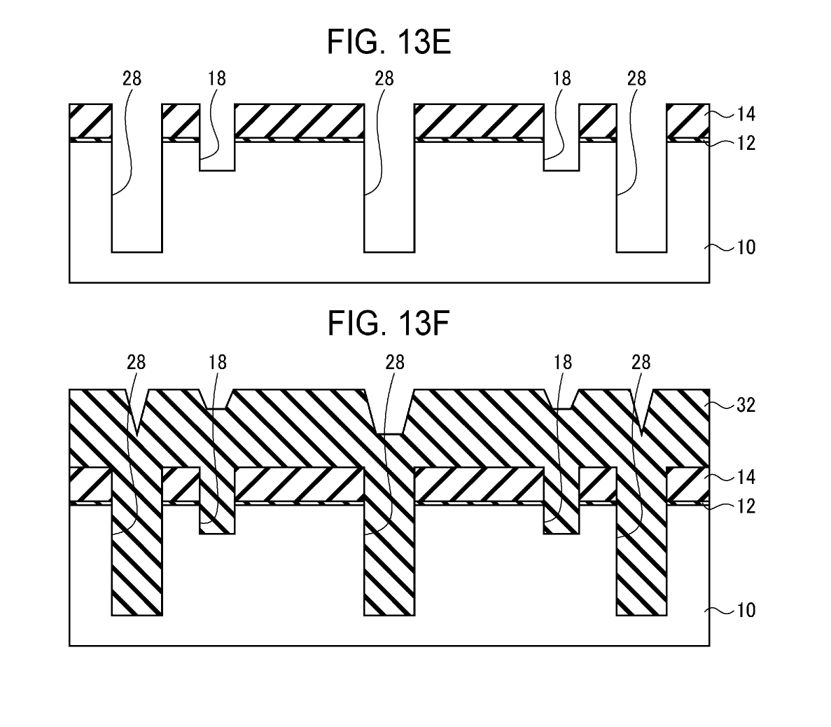

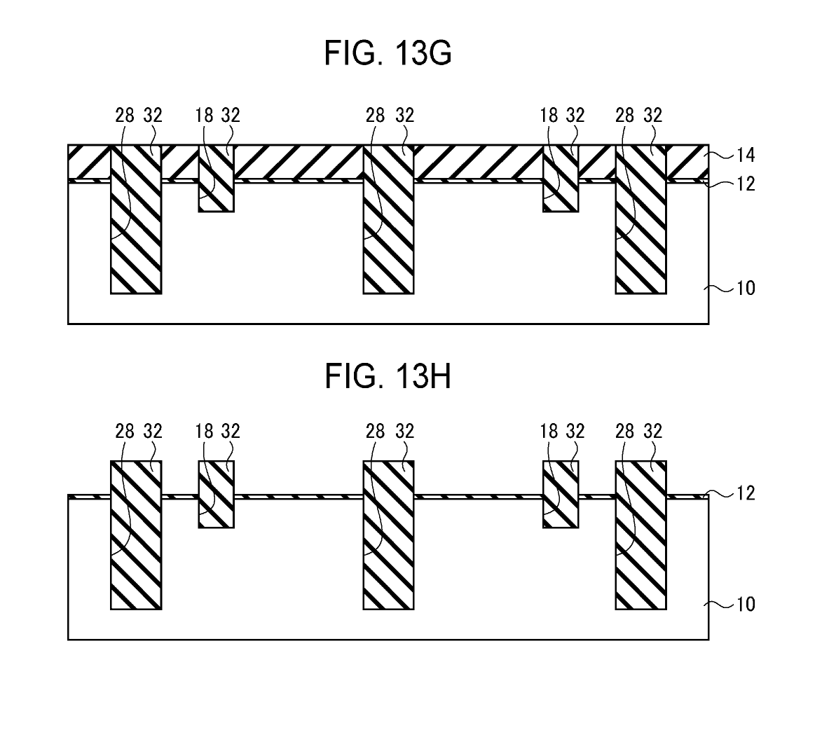

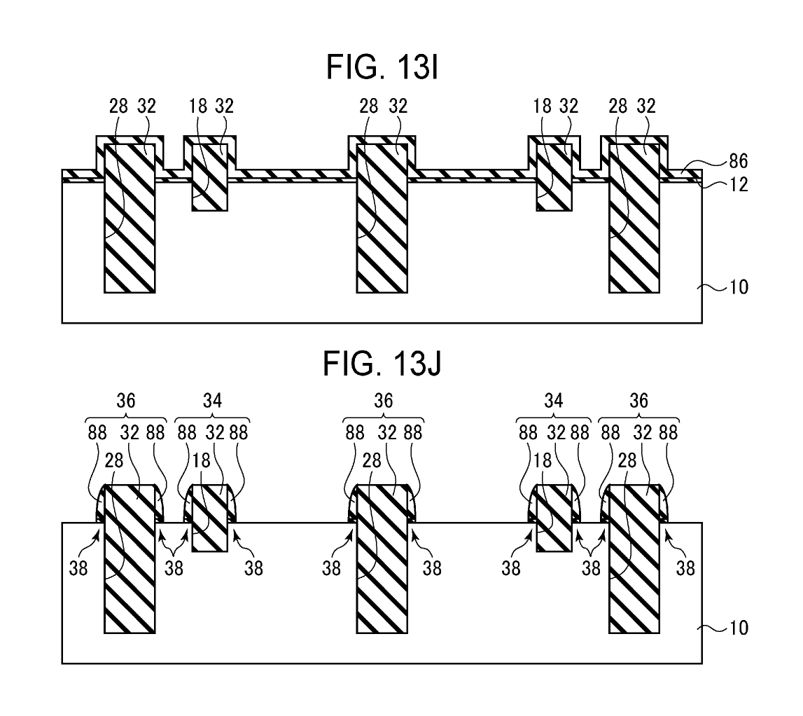

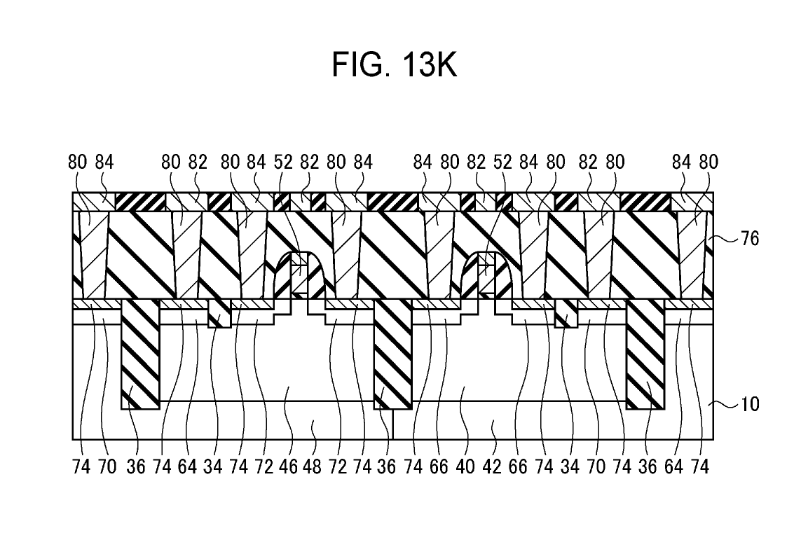

A method of manufacturing the semiconductor device according to a fourth embodiment will be described with reference to FIGS. 13A to 13K. The same members of the present embodiment as those of the semiconductor device and the method of manufacturing the same according to the first to the third embodiments illustrated in FIGS. 1 to 12I are represented by the same reference numbers not to repeat or to simplify the description.

FIGS. 13A-13K are cross-sectional views illustrating the method of manufacturing the semiconductor device according to the present embodiment.

In the present embodiment, another manufacturing method of the semiconductor device according to the second embodiment will be described. FIGS. 13A-13K are the C-C′ line cross-sectional views of FIG. 1.

First, a silicon oxide film 12 of, e.g., an about 5 nm-10 nm thickness is formed above the silicon substrate 10 by, e.g., thermal oxidation method. The oxidation temperature is set to, e.g., 850° C.-1000° C.

Next, a silicon nitride film of, e.g., an about 60 nm-100 nm thickness is formed above the silicon oxide film 12 by, e.g., LPCD method. The growth temperature is set to, e.g., 700° C.-800° C. (FIG. 13A).

Next, the silicon nitride film 14 and the silicon oxide film 12 are patterned by photolithography and dry etching to remove the silicon nitride film 14 and the silicon oxide film 12 in the regions for the device isolation insulating films 34, 36 (FIG. 13B).

Next, the silicon substrate 10 is dry etched with the silicon nitride film 12 as the mask to form the device isolation trenches 18 of, e.g., a 100 nm-200 nm depth in the regions of the silicon substrate 10 for the device isolation insulating films 34, 36 (FIG. 13C).

Next, a photoresist film 24 exposing region for the deep device isolation insulating film 34 and covering the region for the shallow device isolation insulating film 36 which isolates the active region 34a and the active region 34b is formed by photolithography.

Next, the silicon substrate 10 is dry etched with the photoresist film 24 and the silicon nitride film 14 as the mask to further dig down the device isolation trenches in the region for the deep device isolation insulating film 36. Thus, the device isolation trenches 28 of, e.g., a 250 nm-350 nm depth are formed in the region for the deep device isolation insulating film 36 of the silicon substrate 10 (FIG. 13D).

Next, the photoresist film 24 is removed by, e.g., ashing method (FIG. 13E).

Next, by, e.g., thermal oxidation, a silicon oxide film (not illustrated) as a liner film is formed on the inside surfaces of the device isolation trenches 18, 28. This thermal oxidation step also has the effect of rounding the corners of the surface of the silicon substrate 10 in the device isolation trenches 18, 28.

Next, the silicon oxide film 32 of a film thickness sufficient to fill the device isolation trenches 18, 28 is deposited above the entire surface by, e.g., high density plasma CVD method (FIG. 13F).

Next, the silicon oxide film 32 above the silicon nitride film 14 is removed by, e.g., CMP method (FIG. 13G).

Then, the surface of the silicon oxide film 32 is etched with the silicon nitride film 14 as the mask by a prescribed amount by, e.g., wet etching with hydrofluoric acid aqueous solution. This etching is for adjusting the height of the surfaces of the active regions and the height of the surfaces of the device isolation insulating films 34, 36 to be substantially the same in the completed transistor.

Then, the silicon nitride film 24 is removed by, e.g., wet etching with hot phosphoric acid (FIG. 13H).

Next, a silicon oxide film of, e.g., a 10 nm-20 nm thickness is deposited above the entire surface by, e.g., CVD method to form the insulating film 86 of the silicon oxide film (FIG. 13I).

Then, the insulating film 86 is etched back to form the sidewall spacers 88 of the insulating film 86 on the side walls of the silicon oxide film 32 projected beyond the surface of the silicon substrate 10. Thus, the device isolation insulating film 34 having the silicon oxide film 32 buried in the device isolation trench 18 and the sidewall spacer 88, and the device isolation insulating film 36 having the silicon oxide film 32 buried in the device isolation trench 28 and the sidewall spacer 88 are formed.

The thus formed device isolation insulating films 34, 36 have the extensions 38 (the sidewall spacers 88) extended over the surface of the silicon substrate 10 (FIG. 13J).

The width of the extensions 38 of the device isolation insulating films 34, 36 can be controlled by the film thickness of the sidewall spacers 88.

Next, thermal processing is made as required to improve the film quality of the device isolation insulating films 34, 36. For example, the thermal processing of 900° C. and 30 minutes is made in nitrogen atmosphere. This thermal processing makes the device isolation insulating films 34, 36 dense, whereby the etching rate to hydrofluoric acid aqueous solution can be reduced in the later wet etching step, whereby the formation of the recesses 54 on the peripheral surfaces of the device isolation insulating films 34, 36 can be suppressed.

Then, in the same way as in the method of manufacturing the semiconductor device according to the first embodiment illustrated in FIGS. 3J to 3Q, the semiconductor device of the present embodiment is completed (FIG. 13K).

The device isolation insulating films 34, 36 having the extensions 38 are formed, whereby the formation of the recesses 54 on the peripheral surfaces of the device isolation insulating films 34, 36 can be suppressed, whereby the leakage current can be reduced, and the fluctuations of the transistor characteristics can be suppressed.

As described above, according to the present embodiment, the formation of the recesses on the peripheral surfaces of the device isolation insulating films can be suppressed. Consequently, the leakage current and the fluctuations of the characteristics can be reduced, whereby the semiconductor device of high reliability and low power consumption can be realized.

### Modified Embodiments

The above-described embodiments can cover other various modifications.

For example, in the first to the third embodiments, in patterning the silicon nitride film 14, the etching conditions which permit the sidewall deposited film 16 to be deposited are used, but is not essential to form the sidewall film simultaneously with patterning the silicon nitride film 14. A sidewall film in place of the sidewall deposited film 16 may be formed by depositing an insulating film having etching selectivity to silicon after the silicon nitride film 14 has been patterned and etching back the insulating film. With this sidewall film as the mask, the device isolation trenches 28 may be dig down.

In the above-described embodiments, as the substrate, the bulk silicon substrate 10 is used, but in place of the bulk silicon substrate 10, an SOI substrate may be used. In this case, a shallow device isolation insulating film 32 which does not arrive at the buried insulating layer of the SOI substrate, and a deep isolation insulating film 34 which arrives at the buried insulating layer of the SOI substrate are formed. The buried insulating layer of the SOI substrate is used in place of the outer wells (the p-well 42 and the n-well 48) of the double well, whereby the n-well 40 and the p-well 46 can be isolated from the other wells.

In the above-described embodiments, considering that a plurality of transistors are formed on the same semiconductor substrate, examples of isolating the region for the respective transistors from each other have been described. However, in the case that a plurality of transistors are not formed, it is not necessary to form the structures for isolating the transistors from each other. For example, the well need not be double, and the deep device isolation film which is deeper than the well need not be provided.

In the first to the fourth embodiments described above, the wells are formed after the device isolation insulating films 34, 36 have been formed, but after the wells have been formed, the device isolation insulating films 32, 34 may be formed.

The structures, the constituent materials, the manufacturing conditions, etc. of the semiconductor device and the method of manufacturing the same described in the above-described embodiments are exemplified and can be suitably modified or changed in accordance with technical common senses, etc, of those skilled in the art.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present inventions have been described in detail, it should be understood that the various changes, substitutions, and alterations could be made hereto without departing from the spirit and scope of the invention.

What is claimed is:

1. A method of manufacturing a semiconductor device comprising:
forming a first insulating film above a semiconductor substrate;
patterning the first insulating film to form a first opening and a second opening in the first insulating film;
forming a first sidewall film on a side wall of the first opening and a side wall of the second opening;
etching the semiconductor substrate with the first insulating film and the first sidewall film as a mask to dig down the first opening and the second opening into the semiconductor substrate;
after digging down the first opening and the second opening into the semiconductor substrate, removing the first sidewall film to form a first offset portion in the first opening and a second offset portion in the second opening, the first offset portion and the second offset portion including a part of a surface of the semiconductor substrate; and
etching a bottom of the first opening with the first insulating film as a mask.

2. The method of manufacturing a semiconductor device according to claim 1,
further comprising, after forming the first offset portion and the second offset portion, forming a second sidewall film at least above the first offset portion,
wherein in etching the bottom of the first opening, the bottom of the first opening is etched with the first insulating film and the second sidewall film as the mask.

3. The method of manufacturing a semiconductor device according to claim 2, wherein
in forming the second sidewall film, the second sidewall film is formed continuously on a side wall of the semiconductor substrate in the first opening and the first offset portion.

4. The method of manufacturing a semiconductor device according to claim 2, wherein
forming the second sidewall film and etching the bottom of the first opening include etching the semiconductor substrate under conditions which allow a deposition of a reaction product at least above the first offset portion.

5. The method of manufacturing a semiconductor device according to claim 2, wherein
forming the second sidewall film includes
forming a second insulating film in the first opening; and
etching the second insulating film to leave the second insulating film at least above the first offset portion.

6. The method of manufacturing a semiconductor device according to claim 2, further comprising:
before forming the second sidewall film, forming an etching mask above the second opening; and
after etching the bottom of the first opening, removing the etching mask.

7. The method of manufacturing a semiconductor device according to claim 2,
further comprising: after etching the bottom of the first opening,
removing the second sidewall film;
forming a first device isolation insulating film in the first opening, and a second device isolation insulating film in the second opening; and
after forming the first device isolation insulating film and the second device isolation insulating film, removing the first insulating film,
wherein the first device isolation insulating film has a first extension extended over the first offset portion, and the second device isolation insulating film has a second extension extended over the second offset portion.

8. The method of manufacturing a semiconductor device according to claim 7,
further comprising after forming the first device isolation insulating film and the second device isolation insulating film, etching surfaces of the first device isolation insulating film and the second device isolation insulating film,
wherein the film thickness of the first sidewall film is so set that the first device isolation insulating film above the first offset portion and the second device isolation insulating film above the second offset portion are not all removed in etching the surfaces of the first device isolation insulating film and the second device isolation insulating film.

9. The method of manufacturing a semiconductor device according to claim 7, wherein
the second device isolation insulating film defines a first active region and a second active region, and
the first device isolation insulating film defines a transistor forming region including the first active region and the second active region.

10. The method of manufacturing a semiconductor device according to claim 9, wherein
the first active region includes source/drain regions and a body region; and
the second active region includes a body contact region.

11. A method of manufacturing a semiconductor device comprising:
forming a first insulating film above a semiconductor substrate;
patterning the first insulating film to form a first opening and a second opening in the first insulating film;
etching the semiconductor substrate with the first insulating film as a mask to dig down the first opening and the second opening into the semiconductor substrate;
etching a bottom of the first opening with the first insulating film as a mask;
forming in the first opening a first buried insulating film having an upper surface positioned higher than a surface of the semiconductor substrate, and forming in the second opening a second buried insulating film having an upper surface positioned higher than the surface of the semiconductor substrate;
after forming the first buried insulating film and the second buried insulating film, removing the first insulating film;
after removing the first insulating film, forming a first sidewall film on a side wall of the first buried insulating film and the second buried insulating film positioned higher than the surface of the semiconductor substrate to form a first device isolation insulating film including the first buried insulating film and the first sidewall film, and a second device isolation insulating film including the second buried insulating film and the first sidewall film.

12. The method of manufacturing a semiconductor device according to claim 11, wherein
forming the first sidewall film includes:
forming a second insulating film above the semiconductor substrate, the first buried insulating film and the second buried insulating film; and
etching a part of the second insulating film to leave the second insulating film on the side walls of the first buried insulating film and the second buried insulating film positioned higher than the surface of the semiconductor substrate.

13. The method of manufacturing a semiconductor device according to claim 11, further comprising:
thermally processing the first sidewall film.

14. The method of manufacturing a semiconductor device according to claim 11, further comprising:
before forming the second sidewall film, forming an etching mask above the second opening; and
after etching the bottom of the first opening, removing the etching mask.

15. The method of manufacturing a semiconductor device according to claim 11,
further comprising after forming the first device isolation insulating film and the second device isolation insulating film, etching surfaces of the first device isolation insulating film and the second device isolation insulating film,
wherein the film thickness of the first sidewall film is so set that the first device isolation insulating film above the first offset portion and the second device isolation insulating film above the second offset portion are not all removed in etching the surfaces of the first device isolation insulating film and the second device isolation insulating film.

16. The method of manufacturing a semiconductor device according to claim 11, wherein
the second device isolation insulating film defines a first active region and a second active region, and
the first device isolation insulating film defines a transistor forming region including the first active region and the second active region.

17. The method of manufacturing a semiconductor device according to claim 16, wherein
the first active region includes source/drain regions and a body region; and
the second active region includes a body contact region.
